(19) United States
(12) Patent Application Publication
(10) Pub. No.: US 2017/0183775 A1
(43) Pub. Date: Jun. 29, 2017

(54) SUBSTRATE PROCESSING APPARATUS

(71) Applicant: HITACHI KOKUSAI ELECTRIC INC., Tokyo (JP)

(72) Inventor: Tetsuo YAMAMOTO, Toyama-shi (JP)

(73) Assignee: HITACHI KOKUSAI ELECTRIC INC., Tokyo (JP)

(21) Appl. No.: 15/388,815

(22) Filed: Dec. 22, 2016

(30) Foreign Application Priority Data
Dec. 25, 2015 (JP) 2015-253100

(51) Int. Cl. C23C 16/46; H01L 21/67; C23C 16/455; C23C 16/458; C23C 16/52

(52) U.S. Cl. CPC C23C 16/46; C23C 16/458; C23C 16/463; C23C 16/52; C23C 16/45565; H01L 21/67167; H01L 21/67017; H01L 21/67098; H01L 21/67259

(57) ABSTRACT

The present disclosure provides a substrate processing apparatus capable of preventing a heating process from having adverse effects on an operation of supplying gas, even though a shower head is used to supply gas onto a substrate. The substrate processing apparatus includes: a process module having a process chamber where a substrate is processed; a substrate loading/unloading port; a cooling mechanism; a substrate support; a heating unit; a shower head including a dispersion plate made of a material having a first thermal expansion rate; a dispersion plate supporting unit made of a material having a second thermal expansion rate different from the first thermal expansion rate; a first position regulating part configured to regulate positions of the dispersion plate and the dispersion plate supporting unit; and a second position regulating part configured to regulate the positions of the dispersion plate and the dispersion plate supporting unit.

### CROSS-REFERENCE TO RELATED PATENT APPLICATION

This non-provisional U.S. patent application claims priority under 35 U.S.C. §119 of Japanese Patent Application No. 2015-253100, filed on Dec. 25, 2015, the entire contents of which are hereby incorporated by reference.

### BACKGROUND

1. Field

The present disclosure relates to a substrate processing apparatus.

2. Description of the Related Art

Examples of substrate processing apparatuses used in a semiconductor device manufacturing process may include a single-wafer type substrate processing apparatus configured to uniformly supply gas onto a process surface of a substrate using a shower head. More specifically, the single-wafer type substrate processing apparatus is configured to disperse gas through the shower head disposed above a substrate placing surface and a dispersion plate disposed between the shower head and the substrate placing surface while heating a substrate on the substrate placing surface using a heater, and supply gas onto the substrate of the substrate placing surface, thereby processing the substrate (for example, refer to Patent Document 1).

### RELATED ART DOCUMENT

[Patent Document] Patent Document 1. Japanese Patent Publication No. 2015-105405

In the substrate processing apparatus having the above-described configuration, when the substrate is heated, the heating process may affects the dispersion plate. However, although the heating process for the substrate affects the dispersion plate, the substrate processing apparatus must prevent a bad influence on the process of supplying gas onto the substrate, for example, a bad influence such as reduction in uniformity of the gas supply process.

### SUMMARY

Described herein is a technique capable of preventing a substrate heating process from having adverse affects on an operation of supplying gas, even though the gas is supplied onto a substrate through a shower head.

According to one aspect described herein, a substrate processing apparatus includes: a process module having a process chamber where a substrate is processed; a substrate loading/unloading port installed at one of walls defining the process module; a cooling mechanism installed about the substrate loading/unloading port; a substrate support disposed in the process chamber and having a substrate placing surface where the substrate is placed; a heating unit configured to heat the substrate; a shower head disposed to face the substrate placing surface, the shower head including a dispersion plate made of a material having a first thermal expansion rate; a dispersion plate supporting unit configured to support the dispersion plate, wherein the dispersion plate supporting unit is made of a material having a second thermal expansion rate different from the first thermal expansion rate; a first position regulating part disposed at a side where substrate loading/unloading port is installed, wherein the first position regulating part is configured to regulate positions of the dispersion plate and the dispersion plate supporting unit; and a second position regulating part disposed at a side opposite to the side where substrate loading/unloading port is installed with the process chamber therebetween and in-line with the first position regulating part along a substrate loading/unloading direction, wherein the second position regulating part is configured to regulate the positions of the dispersion plate and the dispersion plate supporting unit.

### BRIEF DESCRIPTION OF THE DRAWINGS

FIG. 1 is a diagram exemplifying a transverse cross-section of the entire configuration of a substrate processing apparatus according to a first embodiment described herein.

FIG. 2 is a diagram exemplifying a longitudinal cross-section of the entire configuration of the substrate processing apparatus according to the first embodiment described herein.

FIG. 3 is a diagram schematically illustrating a process chamber of the substrate processing apparatus according to the first embodiment described herein.

FIG. 4 is a diagram schematically illustrating main portions of the process chamber of the substrate processing apparatus according to the first embodiment described herein.

FIGS. 5A and 5B are block diagrams exemplifying a configuration of a controller of the substrate processing apparatus according to the first embodiment described herein.

FIG. 6 is a flowchart exemplifying a substrate processing step according to the first embodiment described herein.

FIG. 7 is a flowchart illustrating a film forming step in the substrate processing step of FIG. 6 in detail.

FIGS. 8A through 8D are diagrams schematically illustrating a specific example of a substrate placement position of the substrate processing apparatus according to the first embodiment described herein.

FIG. 9 is a diagram exemplifying a traverse cross-section of the entire configuration of a substrate processing apparatus according to a second embodiment described herein.

FIG. 10 is a diagram exemplifying a configuration of main portions of a process chamber of the substrate processing apparatus according to the second embodiment described herein.

FIG. 11 is a diagram exemplifying another configuration of the main portions of the process chamber of the substrate processing apparatus according to the second embodiment described herein.

### DETAILED DESCRIPTION

Hereafter, embodiments described herein will be described with reference to the accompanying drawings.

### First Embodiment

First, a first embodiment described herein will be described.

(1) Entire Configuration of Substrate Processing Apparatus

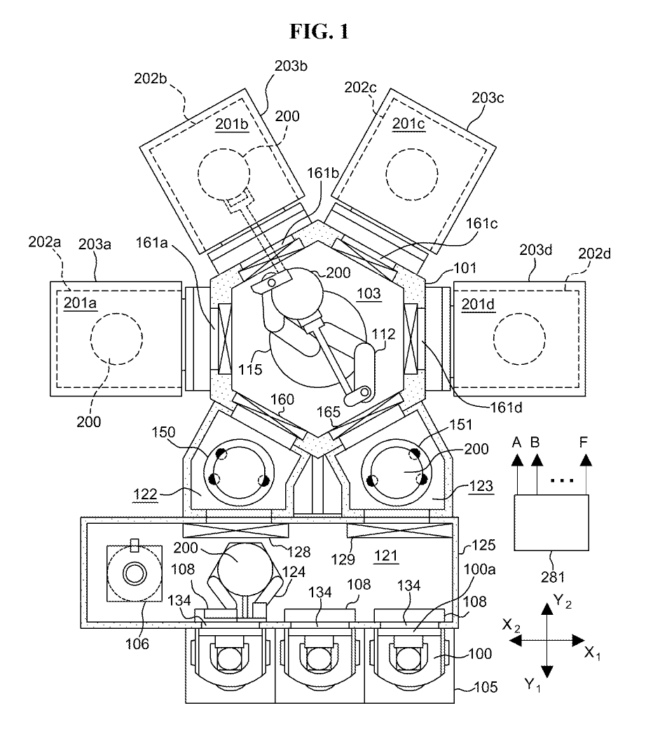

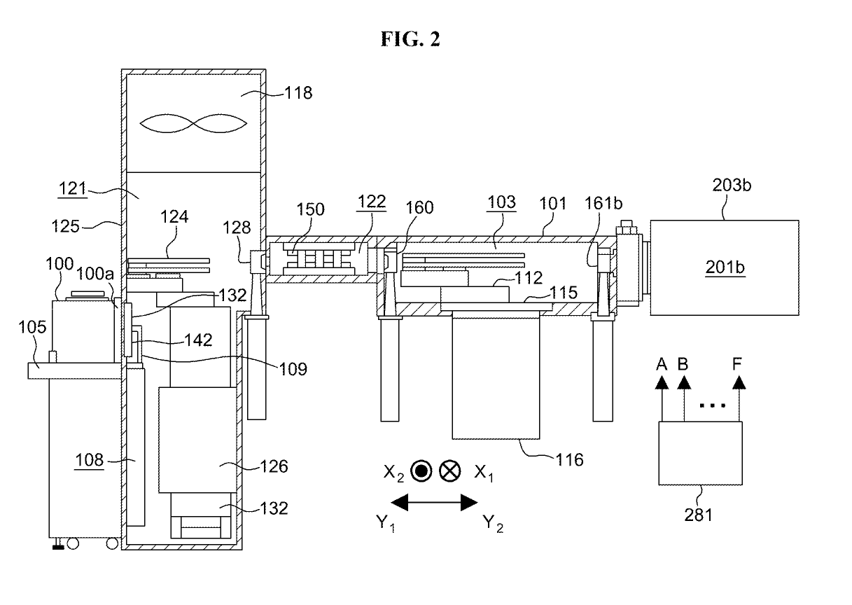

The entire configuration of the substrate processing apparatus according to the first embodiment described herein will be described with reference to FIGS. 1 and 2. FIG. 1 is a diagram exemplifying a transverse cross-section of the entire configuration of the substrate processing apparatus according to the first embodiment, and FIG. 2 is a diagram exemplifying a longitudinal cross-section of the entire configuration of the substrate processing apparatus according to the first embodiment.

As exemplified in FIGS. 1 and 2, the substrate processing apparatus according to the first embodiment is a so-called cluster type apparatus including a plurality of process modules 210a through 201d arranged around a vacuum transfer chamber 103. More specifically, the substrate processing apparatus exemplified in FIGS. 1 and 2 is an apparatus for processing a wafer 200 serving as a substrate, and includes a vacuum transfer chamber (transfer module) 103, load lock chambers (load lock modules) 122 and 233, an atmospheric transfer chamber (front end module) 121, an 10 stage (load port) 105, the plurality of process modules 201a through 201d and a controller 281 serving as a control unit. Hereafter, the respective components will be described in detail. In the following descriptions, X₁ indicates the right side, X₂ indicates the left side, Y₁ indicates the front side, and Y₂ indicates the rear side.

[Vacuum Transfer Chamber]

The vacuum transfer chamber 103 functions as a transfer chamber corresponding to a transfer space where the wafer 200 is transferred under a negative pressure. A housing 101 constituting the vacuum transfer chamber 103 has a hexagonal shape when seen from the top. The load lock chambers 122 and 123 and the process modules 201a through 201d are connected to the respective sides of the hexagonal housing 101 through gate valves 160, 165 and 161a through 161d.

A vacuum transfer robot 112 serving as a transfer robot for transferring the wafer 200 under a negative pressure is installed at substantially the center of the vacuum transfer chamber 103, with a flange 115 set to a base. The vacuum transfer robot 112 is configured to be moved upward/downward by an elevator 116 and the flange 115 while maintaining the airtightness of the vacuum transfer chamber 103.

[Load Lock Chamber]

The load lock chamber 122 for loading the wafer 200 and the load lock chamber 123 for unloading the wafer 200 are connected to two sidewalls positioned at the front among the six sidewalls of the housing 101 constituting the vacuum transfer chamber 103 through the gate valves 160 and 165, respectively. A substrate placing table 150 for loading the wafer 200 is installed in the load lock chamber 122, and a substrate placing table 151 for unloading the wafer 200 is installed in the load lock chamber 123. Each of the load lock chambers 122 and 123 has a structure capable of withstanding a negative pressure.

[Atmospheric Transfer Chamber]

The atmospheric transfer chamber 121 is connected to the front sides of the load lock chambers 122 and 123 through gate valves 128 and 129. The atmospheric transfer chamber 121 is operated substantially under atmospheric pressure.

An atmospheric transfer robot 124 for transferring the wafer 200 is installed in the atmospheric transfer chamber 121. The atmospheric transfer robot 124 is configured to be moved upward/downward by the elevator 126 installed in the atmospheric transfer chamber 121, and reciprocated in the side-to-side direction by a linear actuator 132 (refer to FIG. 2).

A clean unit 118 for supplying clean air is installed above the transfer chamber 121 (refer to FIG. 2). A device 106 for aligning a notch or orientation flat formed on the wafer 200 (hereafter, referred to as “pre-aligner”) is installed in the left side of the atmospheric transfer chamber 121 (refer to FIG. 1).

[IO Stage]

A substrate loading/unloading port 134 and a pod opener 108 are installed at the front of a housing 125 of the atmospheric transfer chamber 121. The substrate loading/unloading port 134 and the pod opener 108 are used to load or unload the wafer 200 into or from the atmospheric transfer chamber 121. The IO stage 105 is installed at the opposite side of the pod opener 108, that is, outside the housing 125 through the substrate loading/unloading port 134.

A plurality of front opening unified pods (FOUP) 100 capable of storing a plurality of wafers 200 are mounted on the 10 stage 105. The FOUP is hereafter referred to as “pod”. The pod 100 is used as a carrier for transferring the wafer 200 such as a silicon (Si) substrate. The pod 100 is configured to store a plurality of unprocessed wafers 200 or processed wafers 200 in a horizontal direction. The pod 100 is supplied onto or discharged from the 10 stage 105 by a rail guided vehicle (RGV) (not illustrated).

The pod 100 on the IO stage 105 is opened/closed by the pod opener 108. The pod opener 108 includes a closer 142 capable of closing/opening a cap 100a of the pod 100 and blocking the substrate loading/unloading port 134 and a driving mechanism 109 for driving the closer 142. As the pod opener 108 opens/closes a substrate entry/exit port of the pod 100 by opening/closing the cap 100a of the pod 100 placed on the IO stage 105, the wafer 200 can be loaded into or unloaded from the pod 100.

[Process Module]

The process modules 201a through 201d which perform a desired process on the wafer 200 are connected to the four sidewalls to which the load lock chambers 122 and 123 are not connected, among the six sidewalls of the housing 101 constituting the vacuum transfer chamber 103, through the gate valves 161a through 161d, and radially arranged around the vacuum transfer chamber 103. The process modules 201a through 201d are constituted by cold wall-type process containers 203a through 203d. Each of the process modules 201a through 201d includes one process chamber. That is, the process modules 210a through 210d include process chambers 202a through 202d, respectively. The process for the wafer 200, which is one of processes for manufacturing a semiconductor or semiconductor device, is performed in each of the process chambers 202a through 202d. In the process chambers 202a through 202d, various substrate treatments may be performed. The various substrate treatments may include a process of forming a thin film on a wafer, a process of oxidizing, nitriding or carbonizing the surface of a wafer, a process of forming a film such as silicide and metal film, a process of etching the wafer of a wafer, a reflow process and the like.

The detailed configurations of the respective process modules 201a through 201d will be described later.

[Controller]

The controller 281 is a control unit for controlling operations of the components constituting the substrate processing apparatus. Thus, the controller 281 is embodied by a computer device including components such as CPU (Central Processing Unit) and RAM (Random Access Memory). The controller 281 is electrically connected to the vacuum transfer robot 112 through a signal line A, electrically connected to the atmospheric transfer robot 124 through a signal line B, electrically connected to the gate valves 160, 161a, 161b, 161c, 161d, 165, 128 and 129 through a signal line C, electrically connected to the pod opener 108 through a signal line D, electrically connected to the pre-aligner 106 through a signal line E, and electrically connected to the clean unit 118 through a signal line F. The controller 281 is configured to transmit operation instructions of the respective components through the signal lines A to F.

The detailed configuration of the controller 281 will be described later.

(2) Configuration of Process Module

Then, the configurations of the respective process modules 201a through 201d will be described in detail.

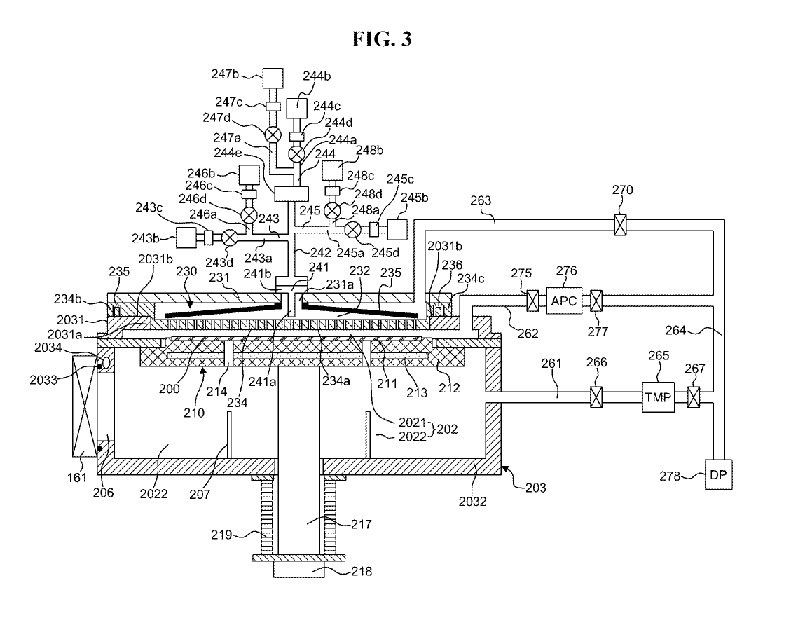

Each of the process modules 201a through 201d functions as a single-wafer type substrate processing apparatus, and has the same configuration. In the first embodiment, one of the process modules 201a through 201d is exemplified to describe the detailed configuration thereof. Since one of the process modules 201a through 201d is exemplified, the process modules 201a through 201d will be simply referred to as “process modules 201” in the following descriptions. Furthermore, the cold wall-type process containers 203a through 203d constituting the respective process modules 201a through 201d are simply referred to as “process containers 203”, the process chambers 202a through 202d formed in the respective process containers 203a through 203d are simply referred to as “process chambers 202”, and the gate valves 161a through 161d installed in the respective process modules 201a through 201d are simply referred to as “gate valves 161”. FIG. 3 is a diagram schematically exemplifying the configuration of the process chamber of the substrate processing apparatus according to the first embodiment described herein.

[Process Container]

As described above, the process module 201 includes the cold wall-type process container 203. The process container 203 is a flat airtight container having a circular transverse cross-section, for example. The process container 203 includes an upper container 2031 made of a ceramic material such as alumina (AlO) and a lower container 2032 made of a metal material such as aluminum (Al) and stainless steel (SUS).

A process chamber 202 is disposed in the process container 203. The process chamber 202 includes a processing space 2021 and a transfer space 2022. The processing space 2021 is disposed at the upper side of the process chamber 202 (the space above a substrate placing table 212 described later), and processes the wafer 200 such as a silicon wafer, and the transfer space 2022 is disposed under the processing space 2021 and surrounded by the lower container 2032.

A substrate loading/unloading port 206 is installed at a side surface of the lower container 2032, that is, one of walls constituting the process container 203, and disposed adjacent to the gate valve 161. The wafer 200 is loaded into the transfer space 2022 through the substrate loading/unloading port 206.

An O-ring 2033 for securing the airtightness of the process container 203 when the gate valve 161 is closed is installed near the substrate loading/unloading port 206 of the lower container 2032. A cooling pipe 2034 is installed rear the substrate loading/unloading port 206 of the lower container 2032, and cools the neighborhood of the substrate loading/unloading port 206 of the lower container 2032, in order to suppress an influence on the O-ring 2033 when a heater 213 described later heats the wafer 200. A refrigerant is supplied to the cooling pipe 2034 through a temperature control unit (not illustrated). The cooling pipe 2034 and the temperature control unit function as a cooling mechanism for cooling the neighborhood region of the substrate loading/unloading port 206. Since the temperature control unit and the refrigerant are publicly known, the detailed descriptions thereof are omitted herein.

Lift pins 207 are installed at the bottom of the lower container 2032. The lower container 2032 has an earth potential. That is, the lower container 2032 is grounded.

[Substrate Placing Table]

A substrate support (susceptor) 210 supporting the wafer 200 is disposed in the processing space 2021. The substrate support 210 includes the substrate placing table 212 and a heater 213. The substrate placing table 212 has a substrate placing surface 211 on which the wafer 200 is placed, and the heater 213 is embedded in the substrate placing table 212. Through-holes 214 through which the lift pins 217 are passed are formed at positions corresponding to the respective lift pins 207 of the substrate placing table 212.

The substrate placing table 212 is supported by a shaft 217. The shaft 217 is installed through the bottom of the process container 203, and connected to an elevating mechanism 218 outside the process container 203. As the elevating mechanism 218 is operated to move upward/downward the shaft 217 and the substrate placing table 212, the substrate placing table 212 may move upward/downward the wafer 200 placed on the substrate placing surface. A bellows 219 covers the lower part of the shaft 217, such that the inside of the processing space 205 is airtightly maintained.

When the wafer 200 is transferred, the substrate placing table 212 is moved downward until the substrate placing surface 211 reaches the position (“wafer transfer position”) of the substrate loading/unloading port 206. When the wafer 200 is processed, the substrate placing table 212 is moved upward until the wafer 200 reaches a processing position (“wafer processing position”) in the processing space 2021. Specifically, when the substrate placing table 212 is moved downward to the wafer transfer position, the upper ends of the lift pins 207 protrude from the substrate placing surface 211, and support the wafer 200 from thereunder. When the substrate placing table 212 is moved upward to the wafer processing position, the lift pins 207 are buried from the substrate placing surface 211, such that the substrate placing surface 211 supports the wafer 200 from thereunder. Since the lift pins 207 come in direct contact with the wafer 200, the lift pins 207 may be made of a material such as quartz and alumina, for example. An elevating mechanism (not illustrated) may be installed on the lift pins 207 so as to move the lift pins 207.

[Shower Head]

The shower head 230 serving as a gas dispersion mechanism is installed above the processing space 2021, that is, at the upstream side of a gas supply direction. The shower head 230 is inserted into a hole 2301a formed at the upper container 2031, for example. The shower head 230 is fixed to the upper container 2031 through a hinge (not illustrated). When maintenance is performed, the shower head 230 may be opened through the hinge.

A lid 231 of the shower head is made of a metal with conductivity and thermal conductivity, for example. The lid 231 of the shower head has a through-hole 231a into which a gas supply pipe 241 serving as a first dispersion mechanism is inserted. The gas supply pipe 241 inserted into the through-hole 231a serves to disperse gas supplied into a shower head buffer chamber 232 which is a space formed in the shower head 230. The gas supply pipe 241 includes a front end portion 241a inserted into the shower head 230 and a flange 241b fixed to the lid 231. The front end portion 241a is formed in a cylindrical shape, for example, and has a dispersion hole (not illustrated) formed at a side surface thereof. Gas supplied through a gas supply unit (supply system) described later is supplied into the shower head buffer chamber 232 through the front end portion 241a and the dispersion hole.

The shower head 230 includes a dispersion plate 234. The dispersion plate 234 is a second dispersion mechanism for dispersing gas supplied through the gas supply unit (gas supply system) described later. The dispersion plate 234 is made of quartz which is a nonmetallic material, for example. The upstream side of the dispersion plate 234 corresponds to the shower head buffer chamber 232, and the downstream side of the dispersion plate 234 corresponds to the processing space 2021. The dispersion plate 234 has a plurality of through-holes 234a formed therein. The dispersion plate 234 is disposed above the substrate placing surface 211 so as to face the substrate placing surface 211 through the processing space 2021. Thus, the shower head buffer chamber 232 communicates with the processing space 2021 through the plurality of through-holes 234a formed in the dispersion plate 234.

The portion of the dispersion plate 234, where the plurality of through-holes 234a are formed, is inserted into a hole 2031a formed in the upper container 2031. The dispersion plate 234 includes flange portions 234b and 234c placed on the upper surface of the upper container 2031, the flange portions 234b and 234c being formed at the periphery of the portion inserted into the hole 2031a. The flange portions 234b and 234c are disposed between the upper container 2031 and the lid 231, and insulate the upper container 2031 and the lid 231 from each other. That is, a pedestal portion 2031b positioned at the peripheral portion of the hole 2031a of the upper container 2031, that is, a portion where the flange portions 234b and 234c are placed functions as a dispersion plate support portion for supporting the dispersion plate 234.

Position regulating unit 235 and 236 for regulating the positions of the upper container 2031 and the dispersion plate 234 are installed at locations where the flange portions 234b and 234b of the dispersion plate 234 and the pedestal portion 2031b of the upper container 2031 overlap each other. The detailed configurations of the position regulating units 235 and 236 will be described later.

A gas guide 235 is installed to form a flow of gas supplied to the shower head buffer chamber 232. The gas guide 235 has a vertex set to the through hole 231a into which the gas supply pipe 241 is inserted, and is cone-shaped with the diameter thereof increasing toward the dispersion plate 234. The lowermost end portion of the gas guide 235 is disposed at a location more outer than the through-hole 234a formed at the outermost portion of the dispersion plate 234. That is, the shower head buffer chamber 232 includes the gas guide 235 for guiding gas supplied through the top of the dispersion plate 234 toward the processing space 2021.

A matcher (not illustrated) and a high-frequency power supply (not illustrated) may be connected to the lid 231 of the shower head. When the matcher and the high-frequency power supply are connected, the matcher and the high-frequency power supply may adjust impedance to generate plasma in the shower head buffer chamber 232 and the processing space 2021.

The shower head 230 may include a heater (not illustrated) embedded therein, the heater serving as a heating source for raising the internal temperatures of the shower head buffer chamber 232 and the processing space 2021. The heater heats the inside of the shower head buffer chamber 232 such that the gas supplied into the shower head buffer chamber 232 is not liquefied. The heater heats the inside of the shower head buffer chamber 232 to about 100° C., for example.

[Gas Supply System]

A common gas supply pipe 242 is connected to the gas supply pipe 241 which is inserted into the through-hole 231a formed in the lid 231 of the shower head 230. The gas supply pipe 241 and the common gas supply pipe 242 communicate with each other therein. The gas supplied through the common gas supply pipe 242 is supplied into the shower head 230 through the gas supply pipe 241 and the gas introduction hole 231a.

A first gas supply pipe 243a, a second gas supply pipe 244a and a third gas supply pipe 245a are connected to the common gas supply pipe 242. The second gas supply pipe 244a is connected to the common gas supply pipe 242 through a remote plasma unit 244e.

A first element-containing gas is supplied mainly through a first gas supply system 243 including the first gas supply pipe 243a, and a second element-containing gas is supplied mainly through a second gas supply system 244 including the second gas supply pipe 244a. An inert gas is supplied mainly through a third gas supply system 245 including the third gas supply pipe 245a, when the wafer 200 is processed. A cleaning gas is supplied mainly through the third gas supply system 245 including the third gas supply pipe 245a, when cleaning the shower head 230 or the processing space 2021.

(First Gas Supply System)

A first gas supply source 243b, an MFC (Mass Flow Controller) 243c serving as a flow controller (flow control unit), and a valve 243d serving as an opening/closing valve are sequentially installed at the first gas supply pipe 243a from the upstream side toward the downstream side of the first gas supply pipe 243a. A gas containing a first element (hereafter, referred to as “first element-containing gas”) is supplied into the shower head 230 through the first gas supply source 243b, the MFC 243c, the valve 243d and the common gas supply pipe 242, which are installed at the first gas supply pipe 243a.

The first element-containing gas is one of processing gases, and serves as a source gas. In the first embodiment, the first element includes silicon (Si), for example. That is, in the first embodiment, the first element-containing gas includes a silicon containing gas, for example, dichlorosilane (SiH₂Cl₂, abbreviated to DCS) gas.

The downstream end of the first inert gas supply pipe 246a is connected to the first gas supply pipe 243a at the downstream side of the valve 243d of the first gas supply pipe 243a. An inert gas supply source 246b, an MFC 246c serving as a flow controller (flow control unit), and a valve 246d serving as an opening/closing valve are sequentially installed at the first inert gas supply pipe 246a from the upstream side toward the downstream side of the first inert gas supply pipe 246a. The inert gas is supplied into the shower head 230 through the inert gas supply source 246b, the MFC 246c and the valve 246d, which are installed at the first inert gas supply pipe 246a, the first gas supply pipe 243a and the common gas supply pipe 242.

In the first embodiment, the inert gas serves as a carrier gas of the first element-containing gas. Preferably, the inert gas does not react with the first element. Specifically, nitrogen (N₂) gas may be used as an inert gas. In addition to N₂ gas, rare gases such as helium (He) gas, neon (Ne) gas and argon (Ar) gas may be used as the inert gas.

The first gas supply system 243 which is also referred to as “silicon containing gas supply system” includes the first gas supply pipe 243a, the MFC 243c and the valve 243d. The first inert gas supply system includes the first inert gas supply pipe 246a, the MFC 246c and the valve 246d. The first gas supply system 243 may further include the first gas supply source 243b and the first inert gas supply system. The first inert gas supply system may further include the inert gas supply source 246b and the first gas supply pipe 243a. The first gas supply system 243 is a part of the processing gas supply system, because the first gas supply system 243 supplies a source gas which is one of processing gases.

[Second Gas Supply System]

The remote plasma unit 244e is installed at the second gas supply pipe 244a. A second gas supply source 244b, an MFC 244c serving as a flow controller (flow control unit), a valve 244d serving as an opening/closing valve and the remote plasma unit 244e are sequentially installed at the second gas supply pipe 244a from the upstream side toward the downstream side of the second gas supply pipe 244a. A gas containing a second element (hereafter, referred to as “second element-containing gas”) is supplied into the shower head 230 through the second gas supply source 244b, the MFC 244c, the valve 244d, the remote plasma unit 244e and the common gas supply pipe 242, which are installed at the second gas supply pipe 244a. At this time, the second element-containing gas is activated to a plasma state by the remote plasma unit 244e, and supplied onto the wafer 200.

The second element-containing gas is one of processing gases, and serves as a reactive gas or modification gas. In the first embodiment, the second element-containing gas contains the second element different from the first element. The second element includes nitrogen (N), for example. That is, the second element-containing gas includes a nitrogen containing gas, for example, ammonia (NH₃) gas.

The downstream end of a second inert gas supply pipe 247a is connected to the downstream side of the valve 244d of the second gas supply pipe 244a. An inert gas supply source 247b, an MFC 247c serving as a flow controller (flow control unit), and a valve 247d serving as an opening/closing valve are sequentially installed at the second inert gas supply pipe 247a from the upstream side toward the downstream side of the second inert gas supply pipe 247a. The inert gas is supplied into the shower head 230 through the inert gas supply source 247b, the MFC 247c and the valve 247d, which are installed at the second inert gas supply pipe 247a, the second gas supply pipe 244a and the common gas supply pipe 242.

In the first embodiment, the inert gas serves as a carrier gas or dilution gas during the substrate processing process. Specifically, N₂ gas may be used as the inert gas. In addition to N₂ gas, rare gases such as He gas, Ne gas and Ar gas may be used as the inert gas.

The second gas supply system 244 which is also referred to as “nitrogen containing gas supply system” includes the second gas supply pipe 244a, the MFC 244c and the valve 244d. The second inert gas supply system includes the second inert gas supply pipe 247a, the MFC 247c and the valve 247d. The second gas supply system 244 may further include the second gas supply source 244b, the remote plasma unit 244e and the second inert gas supply system. The second inert gas supply system may further include the inert gas supply source 247b, the second gas supply pipe 244a and the remote plasma unit 244e. The second gas supply system 244 is a part of the processing gas supply system, because the second gas supply system 244 supplies a reactive gas or modification gas which is one of processing gases.

[Third Gas Supply System]

A third gas supply source 245b, an MFC 245c serving as a flow controller (flow control unit), and a valve 245d serving as an opening/closing valve are sequentially installed at the third gas supply pipe 245a from the upstream side toward the downstream side of the third gas supply pipe 245a. The inert gas is supplied into the shower head 230 through the third gas supply source 245b, the MFC 245c and the valve 245d, which are installed at the third gas supply pipe 245a, and the common gas supply pipe 242.

The inert gas supplied from the third gas supply source 245b serves as a purge gas for purging gas which remains in the process container 203 or the shower head 230 during the substrate processing process. The inert gas supplied from the third gas supply source 245b may act as a carrier gas or dilution gas of the cleaning gas at the cleaning step. For example, N₂ gas may be used as the inert gas. In addition to N₂ gas, rare gases such as He gas, Ne gas and Ar gas may be used as the inert gas.

The downstream end of a cleaning gas supply pipe 248a is connected to the downstream side of the valve 245d of the third gas supply pipe 245a. A cleaning gas supply source 248b, an MFC 248c serving as a flow controller (flow control unit), and a valve 248d serving as an opening/closing valve are sequentially installed at the cleaning gas supply pipe 248a from the upstream side toward the downstream side of the cleaning gas supply pipe 248a. The cleaning gas is supplied into the shower head 230 through the cleaning gas supply source 248b, the MFC 248c and the valve 248d, which are installed at the cleaning gas supply pipe 248a, the third gas supply pipe 245a and the common gas supply pipe 242.

The cleaning gas supplied from the cleaning gas supply source 248b acts as a cleaning gas for removing materials such as by-products adhering to the shower head 230 or the process container 203 at a cleaning step. For example, nitrogen trifluoride (HF₃) gas may be used as the cleaning gas. In addition to NF₃ gas, hydrogen fluoride (HF) gas, chlorine trifluoride (CIF₃) gas, fluorine (F₂) gas and combinations thereof may be used as the cleaning gas.

The third gas supply system 245 includes the third gas supply pipe 245a, the MFC 245c and the valve 245d. A cleaning gas supply system includes the cleaning gas supply pipe 248a, the MFC 248c and the valve 248d. The third gas supply system 245 may further include the third gas supply source 245b and the cleaning gas supply system. The cleaning gas supply system may further include the cleaning gas supply source 248b and the third gas supply pipe 245a.

[Gas Exhaust System]

An exhaust system for exhausting the atmosphere of the process container 203 includes a plurality of exhaust pipes connected to the process container 203. Specifically, the exhaust system includes an exhaust pipe (first exhaust pipe) 261 connected to the transfer space 2022, an exhaust pipe (second exhaust pipe) 262 connected to the processing space 2021, and an exhaust pipe (third exhaust pipe) 263 connected to the shower head buffer chamber 232. An exhaust pipe (fourth exhaust pipe) 264 is connected to the downstream sides of the exhaust pipes 261, 262 and 263.

The exhaust pipe 261 is connected to a side surface or bottom surface of the transfer space 2022. A TMP (Turbo Molecular Pump) 265 serving as a vacuum pump for providing high vacuum or ultra-high vacuum is installed at the exhaust pipe 261. The TMP 265 is also referred to as “first vacuum pump”. Valves 266 and 267 serving as opening/closing valves are installed at the upstream and downstream sides of the TPM 265 of the exhaust pipe 261, respectively.

The exhaust pipe 262 is connected to a side surface of the processing space 2021. An APC (Automatic Pressure Controller) 276 serving as a pressure controller for controlling the internal pressure of the processing space 2021 to a predetermined pressure is installed at the exhaust pipe 262. The APC 276 includes a valve body (not illustrated) capable of adjusting an opening degree thereof, and adjusts the conductance of the exhaust pipe 262 according to an instruction from the controller 280. Valves 275 and 277 serving as opening/closing valves are installed at the upstream and downstream sides of the APC 276, respectively.

The exhaust pipe 263 is connected to a side surface or upper surface of the shower head buffer chamber 232. A valve 270 serving as an opening/closing valve is installed at the exhaust pipe 263.

A DP (Dry Pump) 278 is installed at the exhaust pipe 264. Referring to FIG. 3, the exhaust pipe 263, the exhaust pipe 262 and the exhaust pipe 261 are sequentially connected to the exhaust pipe 264 from the upstream side toward the downstream side of the exhaust pipe 264. The DP 278 is installed at the downstream side of the portions of the exhaust pipe 264, to which the exhaust pipe 263, the exhaust pipe 262 and the exhaust pipe 261 are connected. The DP 278 exhausts the atmospheres of the shower head buffer chamber 232, the processing space 2021 and the transfer space 2022 through the exhaust pipe 263, the exhaust pipe 262 and the exhaust pipe 261, respectively. The DP 278 may function as an auxiliary pump of the TMP 265, when the TMP 265 is operated. That is, since the TMP 265 serving as a high vacuum (or ultra-high vacuum) pump has difficulties in independently exhausting the atmosphere to the atmospheric pressure, the DP 278 is used as an auxiliary pump which exhausts the atmosphere to the atmospheric pressure.

(3) Configurations of Dispersion Plate and Position Regulating Unit

Next, the configurations of the dispersion plate 234 installed in the shower head 230 and the position regulating units 235 and 236 for regulating the position of the dispersion plate 234 will be described in detail.

When the wafer 200 is processed in the above-described process chamber 201, the wafer 200 to be processed is moved upward to the wafer processing position, and the heater 213 of the substrate placing table 212 heats the wafer 200. At this time, while the heater 213 heats the wafer 200, the shower head 230 is also heated at high temperature. If a portion of the shower head 230, which comes in contact with gas, is made of a metallic material, metal pollution from the shower head 230 to the wafer 200 may occur. Thus, the dispersion plate 234 of the shower head 230 is made of quartz which is a nonmetallic material.

The pedestal portion 2031b of the upper container 2031, which supports the dispersion plate 234, is made of alumina which is a ceramic material. Thus, the dispersion plate 234 and the pedestal portion 2031b of the upper container 2031 have different thermal expansion rates. Specifically, the thermal expansion rate (thermal expansion coefficient) of quartz is 6.0×10⁻⁷/° C. (hereafter, referred to as “first thermal expansion rate”), and the thermal expansion rate of the alumina is 7.1×10⁻⁶/° C. (hereafter, referred to as “second thermal expansion rate”). That is, the dispersion plate 234 is made of a material having the first thermal expansion rate, and the pedestal portion 2031b of the upper container 2031 is made of a material having the second thermal expansion rate different from the first thermal expansion rate.

When the dispersion plate 234 has a difference in thermal expansion rate from the pedestal portion 2301b of the upper container 2031, deformations (extensions) of the dispersion plate 234 and the pedestal portion 2301b of the upper container 2031 are different from each other in case where the dispersion plate 234 and the pedestal portion 2031b of the upper container 2031 are heated to high temperature by the heater 213 of the substrate placing table 212. For example, since the thermal expansion rate of quartz forming the dispersion plate 234 is 6.0×10⁻⁷/° C., the dispersion plate 234 is extended by 0.09 mm(=6.0×10⁻⁷×300×500) when a temperature change Δt is 300° C. and the length L is 500 mm. Furthermore, when the temperature change Δt is 400° C. and the length L is 500 mm, the dispersion plate 234 is extended by 0.12 mm(=6.0×10⁻⁷×400×500). Moreover, when the temperature change Δt is 500° C. and the length L is 500 mm, the dispersion plate 234 is extended by 0.15 mm(=6.0×10⁻⁷×500×500) On the other hand, since alumina forming the pedestal portion 2031b of the upper container 2031 has a thermal expansion rate of 7.1×10⁻⁶/° C., the pedestal portion 2031b is extended by 1.1 mm(=7.1×10⁻⁶×300×500) in case where the temperature change Δt is 300° C. and the length L is 500 mm. Furthermore, when the temperature change Δt is 400° C. and the length L is 500 mm, the pedestal portion 2031b is extended by 1.4 mm(=7.1×10⁻⁶×400×500). Moreover, when the temperature change Δt is 500° C. and the length L is 500 mm, the pedestal portion 2031b is extended by 1.8 mm(=7.1×10⁻⁶×500×500).

The reason why the dispersion plate 234 is made of a material having a low thermal expansion rate is in order to prevent a gas flow rate from being changed by an unintended expansion in diameter of the through-hole 234a, when the dispersion plate 234 is heated to high temperature by the heater 213 of the substrate placing table 212. Furthermore, the reason why the upper container 2031 is made of a material having a high thermal expansion rate is that securing mechanical strength was preferentially considered because the process chamber 201 has a vacuum chamber structure.

Considering such a difference in thermal expansion rate, the dispersion plate 234 and the pedestal portion 2031b of the upper container 2031 cannot be fixed by a fixing part such as a screw. When the dispersion plate 234 and the pedestal portion 2031b of the upper container 2031 are fixed by a fixing part such as a screw, any one of the dispersion plate 234 and the pedestal portion 2031b of the upper container 2031 may be damaged. Thus, in the substrate processing apparatus described in the first embodiment, the relative position of the dispersion plate 234 and the pedestal portion 2031b of the upper container 2031 may be fixed through the position regulating units 235 and 236.

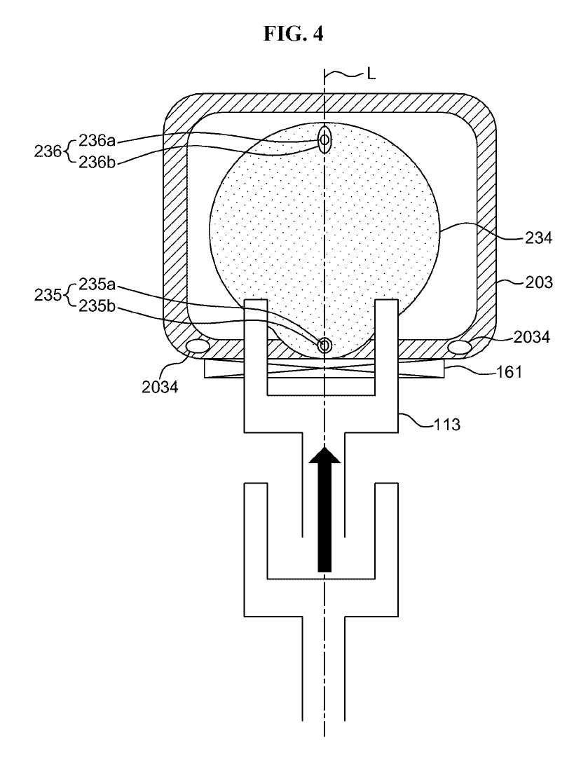

Hereafter, the configurations of the position regulating units 235 and 236 will be described in detail. FIG. 4 is a diagram exemplifying a configuration of main components of the process chamber of the substrate processing apparatus according to the first embodiment described herein.

The position regulating units 235 and 236 are components for regulating the positions of the dispersion plate 234 and the pedestal portion 2031b of the upper container 2031, the pedestal portion 2031b functioning as a dispersion plate support portion. The position regulating units 235 and 236 include a first position regulating part 235 and a second position regulating part 236. The first position regulating part 235 is disposed at a side of the process container 203, where the substrate loading/unloading port 206 is installed (that is, a cooling pipe 2034 is installed), and the second position regulating part 236 is disposed at a side facing the side where the substrate loading/unloading port 206 is installed (that is, a wall facing the wall where the substrate loading/unloading port 206 is installed, among the walls constituting the process container 203), with the processing space 2021 interposed therebetween.

The first and second position regulating parts 235 and 236 are disposed along the loading/unloading direction of the wafer 200 through the substrate loading/unloading port 206. Specifically, the first and second position regulating parts 235 and 236 are disposed on a virtual line L which passes through the center of the substrate loading/unloading port 206 and extends along the loading/unloading direction of the wafer 200 through the substrate loading/unloading port 206, when the substrate loading/unloading port 206 is seen from the top. As illustrated in FIG. 4, the dispersion plate 234 of which the position is regulated by the first and second position regulating parts 235 and 236 is symmetrically disposed with respect to the virtual line L. The loading/unloading direction of the wafer 200 is specified by the vacuum transfer robot 112. That is, the loading/unloading direction of the wafer 200 coincides with the moving direction of the end effector 113 of the vacuum transfer robot 112 as indicated by an arrow of FIG. 4.

The first position regulating part 235 positioned at the substrate loading/unloading port 206, between the first and second position regulating parts 235 and 236, has a first convex portion 235a and a first concave portion 235b. The first convex portion 235a has a pin shape protruding upward from the pedestal portion 2031b of the upper container 2031, and the first concave portion 235b is formed in the dispersion plate 234 and has a circular shape into which the first convex portion 235a is inserted. Since the cooling pipe 2034 is installed at the portion where the first position regulating part 235 is disposed, a temperature rise of the position where the first position regulating part 235 is disposed is suppressed. Considering such a structure, the first position regulating part 235 includes the circular first concave portion 235b.

The second position regulating part 236 includes a second convex portion 236a and a second concave portion 236b. The second convex portion 236a has a pin shape protruding upward from the pedestal portion 2031b of the upper container 2031, and the second concave portion 236b is formed in the dispersion plate 234 and has an elliptical shape into which the second convex portion 236a is inserted. That is, the second position regulating part 236 includes the elliptical second concave portion 236b. Thus, although the dispersion plate 234 or the pedestal portion 2031b of the upper container 2031 is deformed (extended) while being heated by the heater 213 of the substrate placing table 212, damage of the dispersion plate 234 or the pedestal portion 2031b of the upper container 2031 is suppressed by a margin provided by the elliptical second concave portion 236b.

The elliptical second concave portion 236b constituting the second position regulating part 236 has a major axis along the loading/unloading direction of the wafer 200 through the substrate loading/unloading port 206. That is, the direction of the major axis of the second concave portion 236b coincides with the loading/unloading direction of the wafer 200 (that is, the moving direction of the end effector 113 of the vacuum transfer robot 112), while coinciding with the arrangement direction of the first and second position regulating parts 235 and 236. Thus, although the dispersion plate 234 or the pedestal portion 2031b of the upper container 2031 is deformed (extended) while being heated by the heater 213 of the substrate placing table 212, the deformation (extension) direction is regulated along the moving direction of the end effector 113 of the vacuum transfer robot 112.

The first and second position regulating parts 235 and 236 including the pin-shaped convex portions 235a and 236a disposed at the pedestal portion 2031b and the hole-shaped concave portions 235b and 236b disposed at the dispersion plate 234, respectively, are exemplified in the first embodiment. However, the technique described herein is not limited thereto. That is, the first and second position regulating parts 235 and 236 may have the opposite convex-concave relation to the configuration exemplified in the first embodiment, as long as the first and second position regulating parts 235 and 236 can regulate the position of the dispersion plate 234 with respect to the pedestal portion 2031b of the upper container 2031. Furthermore, the first and second position regulating parts 235 and 236 may be implemented through other publicly known position regulating techniques, in addition to the pins and holes.

(4) Configuration of Controller

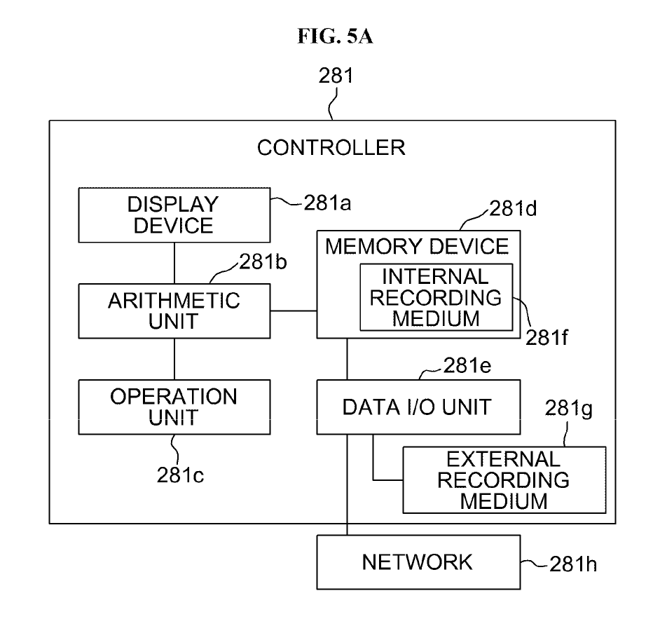

Next, the configuration of the controller 281 will be described in detail. FIGS. 5A and 5B are block diagrams exemplifying the configuration of the controller of the substrate processing apparatus according to the first embodiment described herein.

[Hardware Configuration]

The controller 281 is a control unit for controlling operations of the components constituting the substrate processing apparatus, and embodied by a computer device. Specifically, as illustrated in FIG. 5A, the controller 281 includes the following hardware resources: a display device 281a such as a liquid crystal monitor, an arithmetic unit 281b embodied by a combination of components such as CPU and RAM, an operation unit 281c such as a keyboard and mouse, a memory device 281d such as flash memory and HDD (Hard Disk Drive), and a data I/O unit 281e such as an external interface. Among the hardware resources, the memory device 281d includes an internal recording medium 281f. The data I/O unit 281e is connected to a network 281h. The controller 281 is connected to another component within the substrate processing apparatus, for example, a robot driving unit 283 or upper apparatus (not illustrated) through the network 281h. The controller 281 may include an external recording medium 281g connected to the data I/O unit 281e, instead of the internal recording medium 281f. The controller 281 may include both of the internal recording medium 281f and the external recording medium 281g.

The controller 281 includes a hardware resource such as a computer device. The controller 281 functions as a control unit which executes a program stored in the internal recording medium 281f of the memory device 281d, such that the program (software) and the hardware resources cooperate to control the operations of the components of the substrate processing apparatus.

The controller 281 may be embodied by a dedicated computer device, but not limited thereto. The controller 281 may be embodied by a general use computer device. For example, the controller 280 according to the first embodiment may be embodied by preparing the external recording medium 281g storing the above-described program therein, and installing a program in a general purpose computer device through the external recording medium 281g. The external recording medium 281g may include a magnetic disk such as a magnetic tape, flexible disk and hard disk, an optical disk such as CD and DVD, a magneto-optical disk such as MO, and a semiconductor memory such as a USB memory and memory card. The method for supplying a program to the computer device is not limited to the method for supplying a program through the external recording medium 281g. For example, a program may be directly supplied to the computer device through the network 281h such as the Internet or dedicated line, without the external recording medium 281g interposed therebetween. The internal recording medium 281f and the external recording medium 281g of the memory device 281d are constituted by transitory computer readable recording media. Hereafter, they are collectively referred to as “recording media”. In this specification, “recording media” may indicate only the internal recording medium 281f or the external recording medium 281g of the memory device 281d or both of the internal recording medium 281f and the external recording medium 281g. In this specification, “program” may indicate only a control program or application program, or indicate both of the control program and the application program.

[Functional Configuration]

The arithmetic unit 281b of the controller 281 executes a program stored in the internal recording medium 281f of the memory device 281d, and thus performs at least a function of the transfer robot control unit 282 as illustrated in FIG. 5B. In the present embodiment, only the configuration in which the arithmetic unit 281b performs the function of the transfer robot control unit 282 is exemplified. However, the arithmetic unit 281b may perform another control function.

The transfer robot control unit 282 controls the position at which the vacuum transfer robot 112 disposed in the vacuum transfer chamber 103 adjacent to the process chamber 201 places the wafer 200 on the substrate placing surface 211 of the substrate placing table 212, that is, “placement position”. The vacuum transfer robot 112 serves to load/unload the wafer 200 through the substrate loading/unloading port 206. Specifically, the transfer robot control unit 282 variably controls the placement position on the substrate placing surface 211 such that a first placement position at which a first wafer 200 is placed differs from a second placement position at which a second wafer 200 processed after the first wafer 200 is placed, depending on the processing situation of the process container 203 (for example, the situation of a heating process by the heater 213 in the substrate placing table 212).

In order to variably control the placement position, the transfer robot control unit 282 includes a detection unit 282a, a calculation unit 282b, an instruction unit 282c and a memory unit 282d. The detection unit 282a detects an operation parameter of the vacuum transfer robot 112. The operation parameter includes at least driving history information of the robot driving unit 283 of the vacuum transfer robot 112 (for example, component such as a driving motor (not illustrated) and a controller (not illustrated) thereof) or position information of the vacuum transfer robot 112. The calculation unit 282b calculates operation data when the vacuum transfer robot 112 is operated, based on the operation parameter detected by the detection unit 282a and one or more pieces of position information on the first placement position and the second placement position where the wafer 200 is placed. The instruction unit 282c issues an instruction to the robot driving unit 283 of the vacuum transfer robot 112 according to the operation data calculated by the calculation unit 282b. The memory unit 282d previously stores various data such as mapping data, which are required when the calculation unit 282b calculates the operation data.

A specific example of the configuration in which the transfer robot control unit 282 variably controls the placement position of the wafer 200 will be described later.

(5) Substrate Processing Step

Next, a process of forming a thin film on a wafer 200 using the above-described process module 201 will be described as one of semiconductor manufacturing processes. In the following descriptions, the controller 281 controls the operations of the components constituting the substrate processing apparatus.

In the first embodiment, a process of forming a silicon nitride (SiN) film as a semiconductor-based thin film on the wafer 200 by alternately supplying DCS gas and NH₃ gas as the first element-containing gas (first processing gas) and the second element-containing gas (second processing gas), respectively, will be exemplified.

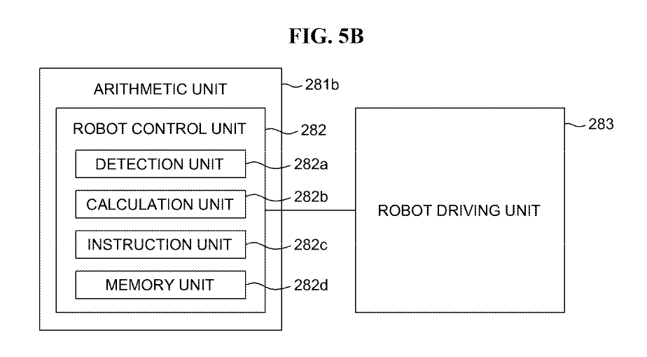

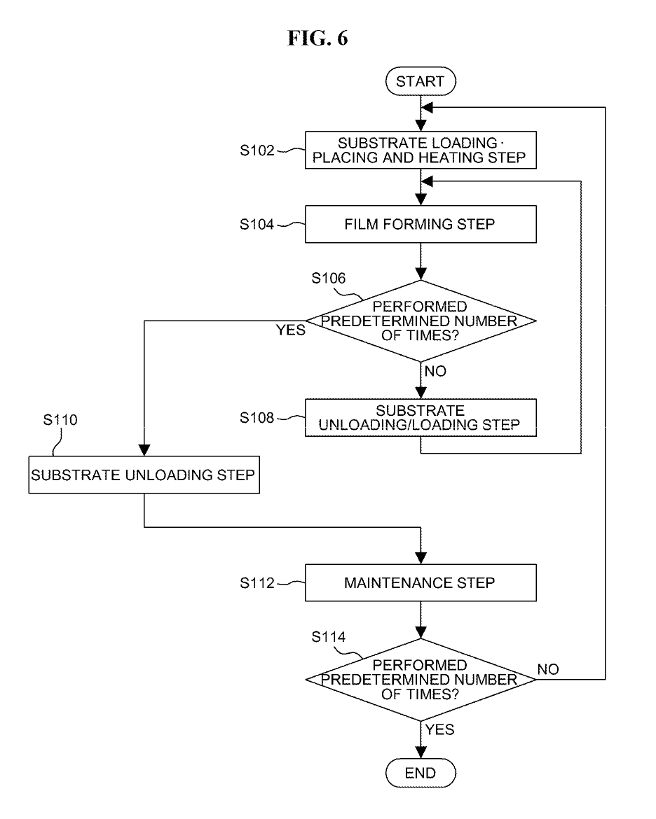

FIG. 6 is a flowchart exemplifying the substrate processing step according to the first embodiment. FIG. 7 is a flowchart exemplifying a film forming step of FIG. 6 in detail.

[Substrate Loading, Placing and Heating Step S102]

First, when the substrate placing table 212 is moved downward to the wafer transfer position for transferring the wafer 200 within the process chamber 202, the lift pins 207 are passed through the through-holes 214 of the substrate placing table 212. As a result, the lift pins 207 protrude by a predetermined height from the surface of the substrate placing table 212. Then, the gate valve 161 is opened to connect the transfer space 2022 to the vacuum transfer chamber 103. The wafer 200 is loaded into the transfer space 2022 from the vacuum transfer chamber 103 by the vacuum transfer robot 112, and placed on the lift pins 207. The wafer 200 is horizontally supported on the lift pins 207 protruding from the surface of the substrate placing table 212.

When the wafer 200 is loaded into the process container 203, the vacuum transfer robot 112 is retracted to the outside of the process container 203. The gate valve 161 is closed to seal the inside of the process container 203. Then, as the substrate placing table 212 is moved upward, the wafer 200 is placed on the substrate placing surface 211 installed on the substrate placing table 212. As the substrate placing table 212 is further moved upward, the wafer 200 is moved upward to the wafer processing position within the above-described processing space 2021.

At this time, the position where the wafer 200 is placed on the substrate placing surface 211 of the substrate placing table 212, that is, the placement position is decided by the position where the wafer 200 is loaded into the transfer space 2022 by the vacuum transfer robot 112. That is, the placement position where the wafer 200 is placed on the substrate placing surface 211 may be controlled in a desired manner according to an operation instruction transmitted to the vacuum transfer robot 112 from the transfer robot control unit 282.

When the wafer 200 is moved upward to the wafer processing position within the processing space 2021 after being loaded into the transfer space 2022, the valves 266 and 267 are closed. Then, the transfer space 2022 is isolated from the TMP 265, and the TMP 265 is isolated from the exhaust pipe 264, such that the process of exhausting the transfer space 2022 through the TMP 265 is ended. As the valves 277 and 275 are opened, the processing space 2021 and the APC 276 communicate with each other, and the APC 276 and the DP 278 communicate with each other. The APC 276 adjusts the conductance of the exhaust pipe 262 to control the flow rate of gas exhausted from the processing space 2021 by the DP 278. Then, the pressure of the processing space 2021 is maintained at a predetermined pressure (for example, a high vacuum of 10⁻⁵ to 10⁻¹ Pa).

At the substrate loading, placing and heating step S102, N₂ gas may be supplied as an inert gas into the process container 203 through the inert gas supply system 245, while the process container 203 is exhausted. That is, while the process container 203 is exhausted by the TMP 265 or the DP 278, the valve 245d of the third gas supply system may be opened to supply N₂ gas into the process container 203, which makes possible to suppress an adhesion of particles to the wafer 200.

When the wafer 200 is placed on the substrate placing table 212, power is supplied to the heater 213 embedded in the substrate placing table 212. The heater 213 adjusts the surface temperature of the wafer 200 to a predetermined temperature. That is, the heater 213 installed in the substrate placing table 212 heats the wafer 200. At this time, the temperature of the heater 213 is adjusted by controlling the state of power supplied to the heater 213, based on temperature information detected by a temperature sensor (not illustrated).

At the substrate loading, placing and heating step S102, the internal pressure of the processing space 2021 is adjusted (controlled) to a predetermined pressure, and the surface temperature of the wafer 200 is adjusted (controlled) to a predetermined temperature. At step S102, “predetermined temperature” and “predetermined pressure” indicate a temperature and pressure at which a SiN film can be formed by an alternate supply method at a film forming step S104 described later. That is, the predetermined temperature and the predetermined pressure correspond to a temperature and pressure at which the first element-containing gas (source gas) supplied at the first processing gas supply step S202 is not autolyzed.

Specifically, the predetermined temperature may range from 500° C. to 650° C. The temperature of 500° C. is a temperature at which a SiN film can be formed but a difference in thermal expansion rate between the dispersion plate 234 and the pedestal portion 2031b of the upper container 2031 becomes conspicuous. The reason why the upper limit temperature is set to 650° C. is that, since the melting point of aluminum (Al) is 660° C., the component such as the process container 203 may not maintain the shape thereof in case where the temperature exceeds the melting point of Al.

The predetermined pressure may range from 50 Pa to 5,000 Pa. The predetermined temperature and the predetermined pressure are also maintained at the film forming step S104.

When the heater 213 within the substrate placing table 212 performs a heating process, a refrigerant is passed through the cooling pipe 2034, thereby loading the region around the substrate loading/unloading port 206. Thus, even when the heater 213 heats the wafer 200 such that the surface temperature of the wafer 200 becomes a predetermined temperature, the influence of the heating process on the O-ring 2033 installed near the substrate loading/unloading port 206 can be suppressed.

[Film Forming Step S104]

After the substrate loading, placing and heating step S102, the film forming step S104 is performed. Hereafter, referring to FIG. 7, the film forming step S104 will be described in detail. The film forming step S104 includes a cyclic process of repeating a step of alternately supplying different processing gases.

[First Processing Gas Supply Step S202]

The film forming step S104 starts with a first processing gas supply step S202. At the first processing gas supply step S202, DCS gas which is the first element-containing gas is supplied as a first processing gas. When the DCS gas is supplied, the valve 243d is opened, and the MFC 243c adjusts the flow rate of supplied DCS gas to a predetermined flow rate. Through this operation, the DCS gas is supplied into the processing space 2021. The flow rate of supplied DCS gas may range from 100 sccm to 5,000 sccm. At this time, the valve 245d of the third gas supply system is opened, and N₂ gas is supplied through the third gas supply pipe 245a. The N₂ gas may also be supplied through the first inert gas supply system. Before the first processing gas supply step S202, N₂ gas may be supplied through the third gas supply pipe 245a.

The DCS gas supplied into the processing space 2021 is supplied onto the wafer 200. As the DCS gas comes in contact with the surface of the wafer 200, a silicon containing layer is formed as “first element containing layer” on the surface of the wafer 200.

The silicon containing layer has a predetermined thickness and distribution depending on conditions such as the internal pressure of the process container 203, the flow rate of DCS gas, the temperature of the substrate placing table 212, and the time required for the DCS gas to pass through the processing space 2021, for example. A predetermined film may be formed on the wafer 200 in advance. A predetermined pattern may be formed on the wafer 200 or the predetermined film in advance.

When a predetermined time has elapsed after the DCS gas was supplied, the valve 243d is closed to stop supplying the DCS gas. The DCS gas supply time may range from two seconds to 20 seconds.

At the first processing gas supply step S202, the valves 275 and 277 are opened, and the APC 276 adjusts (controls) the internal pressure of the processing space 2021 to a predetermined pressure. At the first processing gas supply step S202, the other valves of the exhaust system, excluding the valves 275 and 277, are all closed.

[Purge Step S204]

After the supply of DCS gas is stopped, N₂ gas is supplied through the third gas supply pipe 245a, and purges the shower head 230 and the processing space 2021. At this time, the valves 275 and 277 are open, and the APC 276 adjusts (controls) the internal pressure of the processing space 2021 to a predetermined pressure. The other valves of the exhaust system, excluding the valves 275 and 277, are all closed. Thus, DCS gas which is not coupled to the wafer 200 at the first processing gas supply step S202 is removed from the processing space 2021 through the exhaust pipe 262 by the DP 278. Then, while N₂ gas is supplied through the third gas supply pipe 245a, the valves 275 and 277 are closed, and the valve 270 is opened. The other valves of the exhaust system are all closed. That is, the processing space 2021 and the APC 276 are isolated from each other, the APC 276 and the exhaust pipe 264 are isolated from each other, and the pressure control by the APC 276 is stopped. The shower head buffer chamber 232 and the DP 278 communicate with each other. Then, DCS gas remaining in the shower head 230 (shower head buffer chamber 232) is exhausted from the shower head 230 through the exhaust pipe 263 by the DP 278.

At the purge step S204, a large amount of purge gas is supplied in order to exclude DCS gas remaining in the wafer 200, the processing space 2021 and the shower head buffer chamber 232. Thus, the exhaust efficiency is improved.

When purging the shower head 230 is ended, the valves 277 and 275 are opened, the pressure control by the APC 276 is resumed, and the valve 270 is closed to isolate the shower head 230 and the exhaust pipe 264 from each other. The other valves of the exhaust system are all closed. While N₂ gas is continuously supplied through the third gas supply pipe 245a, the shower head 230 and the processing space 2021 are continuously purged. Before or after the shower head 230 (shower head buffer chamber 232) is purged through the exhaust pipe 263 at the purge step S204, the shower head 230 and the processing space 2021 are purged through the exhaust pipe 262. However, only the purge operation through the exhaust pipe 263 may be performed. Furthermore, both of the purge operation through the exhaust pipe 263 and the purge operation through the exhaust pipe 262 may be performed at the same time.

[Second Processing Gas Supply Step S206]

When the purging of the shower head buffer chamber 232 and the processing space 2021 is finished, a second processing gas supply step S206 is performed. At the second processing gas supply step S206, the valve 244d is opened, and NH₃ gas which is the second element-containing gas is supplied as the second processing gas into the processing space 2021 through the remote plasma unit 244e and the shower head 230. At this time, the MFC 244c is controlled to adjust the flow rate of NH₃ gas to a predetermined flow rate. The flow rate of supplied NH₃ gas may range from 1,000 sccm to 10,000 sccm. At the second processing gas supply step S206, the valve 245d of the third gas supply system is also opened, and N₂ gas is supplied through the third gas supply pipe 245a. The supply of N₂ gas prevents NH₃ gas from permeating into the third gas supply system.

The NH₃ gas converted into a plasma state by the remote plasma unit 244g is supplied into the processing space 2021 through the shower head 230. The supplied NH₃ gas reacts with the silicon containing layer on the wafer 200. The silicon containing layer formed on the wafer 200 is modified by the plasma of NH₃ gas. Then, a SiN layer containing silicon and nitrogen elements is formed on the wafer 200.

The SiN layer has a predetermined thickness, a predetermined distribution and a predetermined penetration depth of an element such as nitrogen with respect to the silicon containing layer, depending on conditions such as the internal pressure of the process container 203, the flow rate of NH₃, the temperature of the substrate placing table 212, and the power supply state of the plasma generation unit.

When a predetermined time has elapsed after NH₃ gas was supplied, the valve 244d is closed to stop supplying NH₃ gas. The NH₃ gas supply time may range from two seconds to 20 seconds.

At the second processing gas supply step S206, the valves 275 and 277 are opened, and the APC 276 controls the internal pressure of the processing space 2021 to a predetermined pressure, as in the first processing gas supply step S202. The other valves of the exhaust system, excluding the valves 275 and 277, are all closed.

[Purge Step S208]

After the supply of NH₃ gas is stopped, the same purge step S208 as the above-described purge step S204 is performed. Since the operations of the respective components at the purge step S208 are performed in the same manner as the purge step S204, the detailed descriptions thereof are omitted herein.

[Determination Step S210]

The first processing gas supply step S202, the purge step S204, the second processing gas supply step S206 and the purge step S208 may be set to one cycle. The controller 281 determines whether the cycle was performed a predetermined number of times (n times), at step S210. When the cycle is performed the predetermined number of times, a SiN layer having a desired thickness is formed on the wafer 200.

[Determination Step S106]

Referring back to FIG. 6, a determination step S106 is performed after the film forming step S104 including the above-described steps S202 through S210 is performed. The determination step S106 includes determining whether the film forming step S104 was performed a predetermined number of times. At the determination step S106, “predetermined number of times” indicates the number of film forming steps S104 which are repeated to such an extent that maintenance is required.

At the first processing gas supply step S202 of the above-described film forming step S104, DCS gas may leak into the transfer space 2022 so as to permeate into the substrate loading/unloading port 206. At the second processing gas supply step S206, NH₃ gas may also leak into the transfer space 2022 so as to permeate into the substrate loading/unloading port 206. At the purge steps S204 and 208, it is difficult to exhaust the atmosphere of the transfer space 2022. Therefore, when DCS gas and NH₃ gas permeate into the transfer space 2022, the DCS gas and NH₃ gas react with each other. Then, a film such as reaction byproduct is deposited in the transfer space 2022 or on the wall surface of a component such as the substrate loading/unloading port 206. The deposited film may become particles. Therefore, it is necessary to regularly maintain the inside of the process container 203.

Thus, when it is determined at the determination step S106 that the number of film forming steps S104 did not reach the predetermined number of times, it indicates that the maintenance of the inside of the process container 203 does not yet need to be performed. Thus, a substrate loading/unloading step S108 is performed. On the other hand, when it is determined at the determination step S106 that the number of film forming steps S104 reached the predetermined number of times, it is determined that the maintenance of the inside of the process container 203 needs to be maintained. Then, a substrate unloading step S110 is performed.

[Substrate Loading/Unloading Step S108]

At the substrate loading/unloading step S108, the processed wafer 200 is unloaded to the outside of the process container 203. Then, an unprocessed wafer 200 on standby is loaded into the process container 203 in the same sequence as the substrate loading, placing and heating step S102. Then, the film forming step S104 is performed on the loaded wafer 200.

[Substrate Unloading Step S110]

When the processed wafer 200 is unloaded from the process container 203 at the substrate unloading step S110, no wafer 200 is present in the process container 203. Specifically, the processed wafer 200 is unloaded to the outside of the process container 203, and a new unprocessed wafer 200 on standby is not loaded into the process container 203 at the substrate unloading step S110, unlike at the substrate loading/unloading step S108.

[Maintenance Step S112]

After the substrate unloading step S110 is finished, a maintenance step S112 is performed. The maintenance step S112 includes cleaning the inside of the process container 203. Specifically, the valve 248d of the cleaning gas supply system is opened, and cleaning gas is supplied into the shower head 230 and the process container 203 through the third gas supply pipe 245a and the common gas supply pipe 242 from the cleaning gas supply source 248b. The supplied cleaning gas is introduced into the shower head 230 and the process container 203 and then exhausted through the first exhaust pipe 261, the second exhaust pipe 262 or the third exhaust pipe 263. The maintenance step S112 may include a cleaning process of supplying the cleaning gas to remove deposits such as reaction byproducts, which adhere to the inside of the shower head 230 and the inside of the process container 203. The maintenance step S112 is finished after the cleaning process is performed for a predetermined time. At the maintenance step S112, “predetermined time” may be appropriately set in advance, and is not limited to a specific time.

[Determination Step S114]

After the maintenance step S112 is finished, a determination step S114 is performed. The determination step S114 includes determining whether the above-described series of steps S102 through S112 were performed a predetermined number of times. At the determination step S114, “predetermined number of times” indicates the number of times corresponding to a predetermined number of wafers 200 (that is, the number of wafers 200 stored in the pod 100 on the IO stage 105).

When it is determined that the number of times where the series of steps S102 through S112 were performed did not reach the predetermined number of times, the procedure returns to the substrate loading, placing and heating step S102, and the above-described series of steps S102 through S112 are performed. On the other hand, when it is determined that the number of times where the series of steps S102 through S112 were performed reached the predetermined number of times, it indicates that the substrate processing steps for all of the wafers 200 stored in the pod 100 on the IO stage 105 were completed. Thus, the above-described series of steps S102 through S114 are ended.

(6) Substrate Placement Position

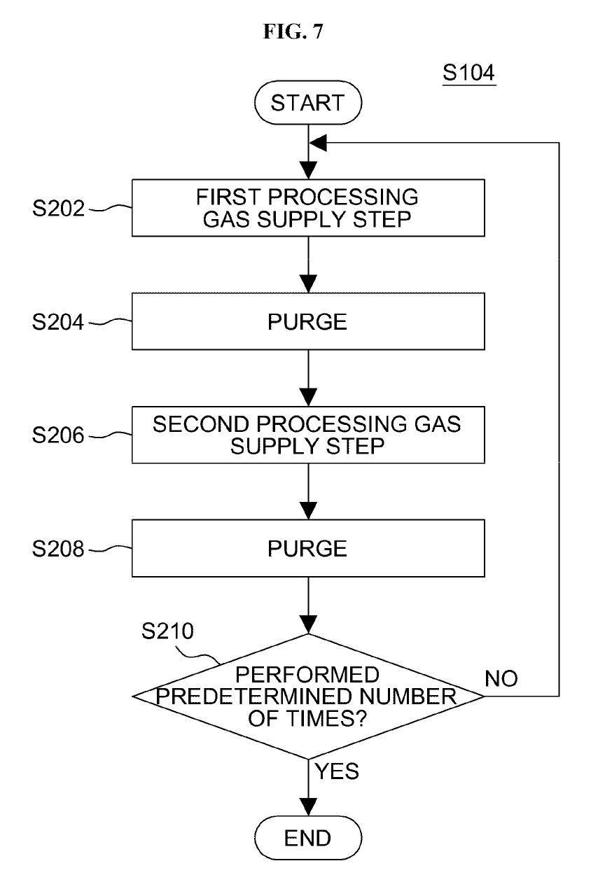

Next, a position where the wafer 200 loaded into the process container 203 by the vacuum transfer robot 112 is placed on the substrate placing surface 211 during the above-described series of substrate processing steps, that is, a placement position will be described. The placement position of the wafer 200 is decided according to the position where the wafer 200 is loaded by the vacuum transfer robot 112. That is, the placement position of the wafer 200 is controlled according to an operation instruction from the transfer robot control unit 282. FIGS. 8A through 8D are diagrams schematically illustrating a specific example of a substrate placement position in the substrate processing apparatus according to the first embodiment.

[Relative Position of Wafer and Dispersion Plate]

When the substrate placing table 212 is moved upward to the wafer processing position, the wafer 200 placed on the substrate placing surface 211 faces the dispersion plate 234 as illustrated in FIG. 8A. Through the through-hole 234a of the dispersion plate 234, gas is supplied onto the wafer 200 on the substrate placing surface 211.

At the initial stage where the first wafer 200 of the first lot starts to be processed, the relative position of the wafer 200 and the dispersion plate 234 at the wafer processing position is set in such a manner that the center position C1 of the wafer 200 and the center position C2 of the dispersion plate 234 coincide with each other, when seen from the top.

As described above, the film forming step S104 includes a cyclic process of repeating a step of alternately supplying different processing gases. During the cyclic process, the amount of the wafer 200 exposed to the processing gases may be raised to shorten the time required for forming one layer. However, when the amount exposed to the processing gases is raised, a larger amount of material (byproduct) which does not contribute to forming a film on the surface of the wafer 200 may be formed. At the film forming step S104, the processing gas which is uniformly supplied from the through-holes 234a of the dispersion plate 234 is exhausted while flowing along the surface of the wafer 200 toward the peripheral portion of the wafer 200 from right under the dispersion plate 234. Thus, a distance by which the processing gas leaking from about the center portion of the dispersion plate 234 flows along the surface of the wafer 200 is different from a distance by which the processing gas leaking from about the peripheral portion of the dispersion plate 234 flows along the surface of the wafer 200. Furthermore, when byproducts are produced about the center portion of the wafer 200, the byproducts flow along the surface of the wafer 200 toward the peripheral portion of the wafer 200. Thus, when a difference occurs in distance by which the processing gas flows along the surface of the wafer 200 or the byproducts flowing toward the peripheral portion of the wafer 200 cause a bad influence or hinder a reaction about the peripheral portion of the wafer 200, a difference may occur in quality between a film formed about the center portion of the wafer 200 and a film formed about the peripheral portion of the wafer 200. The quality may indicate a property such as density or thickness of the film.

Considering the above description, the relative position of the wafer 200 placed on the substrate placing surface 211 of the substrate placing table 212 and the through-holes 234a of the dispersion plate 234 may be constantly retained until the series of substrate processing steps from the initial state are finished. Furthermore, the relative position is also applied to a plurality of wafers 200. For example, the relative position needs to be constantly retained, even while the first wafer 200 of the first lot is processed, while the last wafer 200 of the first lot is processed, while the first wafer 200 of a corresponding lot among a plurality of lots is processed, and while the last wafer 200 of the corresponding lot is processed.

[Influence of Heating Process]

However, the series of substrate processing steps include a heating process performed by the heater 213 within the substrate placing table 212. Thus, both of the substrate placing table 212 having the wafer 200 placed thereon and the dispersion plate 234 for supplying gas onto the wafer 200 are affected by the heating process of the heater 213.

Specifically, as illustrated in FIG. 8B, the substrate placing table 212 and the dispersion plate 234 are deformed (extended) by thermal expansion caused by the influence of the heating process by the heater 213. In particular, when the process for the wafer 200 is repetitively performed, heat is accumulated in the substrate placing table 212 and the dispersion plate 234. Thus, the substrate placing table 212 and the dispersion plate 234 is significantly deformed by thermal expansion. At this time, the substrate placing table 212 is deformed (extended) toward all directions as illustrated in an arrow G1 of FIG. 8B, with the center position thereof set to the axial center. The center position coincides with the center position C1 of the wafer 200. The position of the dispersion plate 234 is regulated by the first position regulating part 235 including the circular first concave portion 235b and the second position regulating part 236 including the elliptical second concave portion 236b. Thus, the dispersion plate 234 is deformed (extended) toward the second position regulating part 236 as indicated by an arrow G2 in FIG. 8B, based on the position of the first position regulating part 235.

Therefore, after the heating process is performed by the heater 213, the difference in deformation (extension) direction may cause a shift a between the center position C1 of the wafer 200 placed on the substrate placing surface 211 of the substrate placing table 212 and the center position C2 of the dispersion plate 234. That is, the relative position of the wafer 200 on the substrate placing surface 211 and the through-holes 234a of the dispersion plate 234 is shifted between the initial state of the substrate processing step and the state after the heating process is started.

Due to such a shift in relative position, the quality of the film formed on the wafer 200 processed at the initial stage of the substrate processing step may differ from the quality of the film formed on the wafer 200 processed afterwards. The quality of the film may indicate a property such as film density and thickness. Such a problem may reduce the yield.

[Variable Control of Placement Position]

Therefore, in order to suppress the shift in relative position of the wafer 200 on the substrate placing surface 211 and the through-holes 234a of the dispersion plate 234 after the substrate processing apparatus described in the first embodiment starts the heating process, the transfer robot control unit 282 variably controls the position where the vacuum transfer robot 112 places the wafer 200, that is, the substrate placement position as described later.

The transfer robot control unit 282 variably controls the placement position of the wafer 200 depending on the processing situation in the process container 203. An example of the processing situation in the process container 203 may include the heating process performed by the heater 213. Specifically, the placement position of the wafer 200 heated by the heater 213 is changed depending on whether the wafer 200 is a wafer 200 which is first loaded and processed in the process container 203 or a wafer 200 which is then loaded and processed in the process container 203. The placement position may consider conditions such as an elapsed time after the heating process is started and the internal temperature of the process container 203 after the heating process is started.

The transfer robot control unit 282 variably controls the placement positions of first and second wafers such that first and second placement positions differ from each other. The first placement position is where the first wafer 200 which is first loaded and processed in the process container 203 is placed, and the second placement position is where the second wafer 200 which is loaded and processed in the process container 203 after the first wafer was processed is placed. The transfer robot control unit 282 places a wafer 200 at the first placement position at the initial stage of the substrate processing step. After the number of heating processes is accumulated, the transfer robot control unit 282 places a wafer 200 at the second placement position. The second placement position is not necessarily set to one location, and may include a plurality of locations depending on the conditions such as the elapsed time after the heating process is started and the internal temperature of the process container 203 after the heating process is started.

The first and second placement positions may be separated by a shift a from each other. For example, when an occurrence of shift a between the center position C1 of the wafer 200 and the center position C2 of the dispersion plate 234 by the heating process is expected, the second placement position is present at a position separated by the shift a from the first placement position along the extension direction of the dispersion plate 234.

Therefore, when the end effector 113 of the vacuum transfer robot 112 which is operated according to an instruction from the transfer robot control unit 282 places the second wafer, the end effector 113 further moves the second wafer by a from the first placement position toward the extension direction (right direction in FIG. 8C) of the dispersion plate 234 as illustrated in FIG. 8C, sets the position to the second placement position, and loads and places the wafer 200 in the process container 203.

Then, when the substrate placing table 212 is moved upward to the wafer processing position, the wafer 200 loaded at the second placement position is placed on the substrate placing surface 211 with the center position C1 shifted by a from the center position of the substrate placing table 212, as illustrated in FIG. 8D. Therefore, although the extension directions of the substrate placing table 212 and the dispersion plate 234 by the heating process are different from each other as indicated by arrows G1 and G2 in FIG. 8D, the center position C1 of the wafer 200 and the center position C2 of the dispersion plate 234 may coincide with each other when seen from the top. That is, as the transfer robot control unit 282 variably controls the placement position with respect to the vacuum transfer robot 112, the above-described shift in relative position by the influence of the heating process may be offset. Therefore, the relative position of the wafer 200 on the substrate placing surface 211 and the through-holes 234a of the dispersion plate 234 may be constantly retained.

[Specific Method for Variably Controlling Placement Position]

The transfer robot control unit 282 variably controls a placement position using the detection unit 282a, the calculation unit 282b, the instruction unit 282c and the memory unit 282d.

Specifically, when the vacuum transfer robot 112 is operated, the detection unit 282a of the transfer robot control unit 282 detects an operation parameter of the vacuum transfer robot 112. The operation parameter may include at least one piece of driving history information of the robot driving unit 283 of the vacuum transfer robot 112 and position information of the vacuum transfer robot 112. The operation parameter may further include other pieces of information such as an elapsed time after the heating process is started and a result obtained by detecting the internal temperature of the process container 203. By detecting the operation parameter, the transfer robot control unit 282 may recognize the operation situation of the vacuum transfer robot 112, for example, the current position of the vacuum transfer robot 112. Since the method for detecting an operation parameter is publicly known, the detailed descriptions thereof are omitted herein.

After the detection unit 282a detects the operation parameter, the calculation unit 282b of the transfer robot control unit 282 calculates driving data of the vacuum transfer robot 112, based on the detected operation parameter and at least one piece of position information on the first placement position and the second placement position. Specifically, the calculation unit 282b determines whether to set the first placement position to the placement position or to set the second placement position to the placement position, based on the detected operation parameter, and calculates driving data required for movement to the set placement position. The position information on the first placement position, which is the placement position in the initial state when the process is started, may be preset in the memory unit 282d through a teaching operation performed in advance. The position information on the second placement position may be preset in the memory unit 282d, like the position information on the first placement position. However, when mapping data specifying the correlation between temperature change and thermal expansion rate is stored in the memory unit 282d, the position information on the second placement position may be calculated by the calculation unit 282b, based on the mapping data.

After the calculation unit 282b calculates the driving data, the instruction unit 282c of the transfer robot control unit 282 issues an operation instruction to the robot driving unit 283 of the vacuum transfer robot 112 according to the calculated driving data. The robot driving unit 283 operates the vacuum transfer robot 112 according to the operation instruction. Thus, the vacuum transfer robot 112 sets any one of the first and second placement positions to the placement position, depending on the processing situation within the process container 203, and then loads the wafer 200 into the process container 203.

(7) Effects of First Embodiment

According to the first embodiment, one or more effects described below can be obtained.

(a) In the first embodiment, the dispersion plate 234 of the shower head 230 is made of quartz which is a nonmetallic material. Thus, although the shower head 230 is heated to high temperature through the heating process by the heater 213, metal pollution to the wafer 200 does not occur. Although the dispersion plate 234 made of a nonmetallic material and the pedestal portion 2031b of the upper container 2031 supporting the dispersion plate 234 are made of materials having different thermal expansion rates, the relative position thereof is regulated by the first and second position regulating parts 235 and 236 which are arranged according to the loading/unloading direction of the wafer 200. Thus, although a component such as the dispersion plate 234 is deformed (extended) by the influence of the heating process of the heater 213, the first and second position regulating parts 235 and 236 may regulate the deformation direction along the moving direction of the end effector 113 of the vacuum transfer robot 112, while preventing the damage of the component such as the dispersion plate 234. That is, although the relative position of the wafer 200 and the through-holes 234a of the dispersion plate 234 is shifted by the deformation of the component such as the dispersion plate 234 due to the influence of the heating process, the shift may be offset through the operation of varying the movement position of the vacuum transfer robot 112. Thus, the relative position of the wafer 200 on the substrate placing surface 211 and the through-holes 234a of the dispersion plate 234 may be constantly retained. Therefore, although the wafer 200 is heated when gas is supplied onto the wafer 200 through the shower head 230, the substrate processing apparatus according to the first embodiment can prevent the heating process from having adverse effects on the supply of gas onto the wafer 200.

(b) In the first embodiment, the first position regulating part 235 is disposed at a side where the substrate loading/unloading port 206 is installed (that is, where the cooling pipe 2034 is installed). The first position regulating part 235 includes the pin-shaped first convex portion 235a and the circular first concave portion 235b into which the first convex portion 235a is inserted. That is, during the position regulating operation by the first and second position regulating parts 235 and 236, the first position regulating part 235 serves as a reference unit, and is cooled by a refrigerant flowing through the cooling pipe 2034. Thus, although the wafer 200 is heated, the substrate processing apparatus can suppress the heating process from having an influence on the first position regulating part 235 serving as the reference unit.

(c) In the first embodiment, the second position regulating part 236 disposed at a side facing the side where the substrate loading/unloading port 206 is installed includes the pin-shaped second convex portion 236a and the elliptical second concave portion 236b into which the second convex portion 236a is inserted. The second concave portion 236b has a major axis along the loading/unloading direction of the wafer 200 through the substrate loading/unloading port 206. That is, when the position regulation is performed by the first and second position regulating parts 235 and 236, the second position regulating part 236 provides a margin for deformation (extension) of a component such as the dispersion plate 234. Therefore, although the wafer 200 is heated, the first and second position regulating parts 235 and 236 may regulate the deformation direction of the component such as the dispersion plate 234 such that the deformation direction follows the moving direction of the end effector 113 of the vacuum transfer robot 112, while preventing the damage of the component such as the dispersion plate 234.

(d) In the first embodiment, the first and second position regulating parts 235 and 236 are disposed on the virtual line L which passes through the center of the substrate loading/unloading port 206 and extends along the loading/unloading direction of the wafer 200 through the substrate loading/unloading port 206, when the substrate loading/unloading port 206 is seen from the top. Therefore, the dispersion plate 234 of which the position is regulated by the first and second position regulating parts 235 and 236 is symmetrically disposed with respect to the virtual line L. Although the dispersion plate 234 is deformed (extended) by the heating process for the wafer 200, the dispersion plate 234 is symmetrically maintained with respect to the virtual line L in the direction crossing the loading/unloading direction of the wafer 200. Thus, a shift in relative position of the wafer 200 on the substrate placing surface 211 and the through-holes 234a of the dispersion plate 234 can be suppressed as much as possible.

(e) In the first embodiment, the wafer 200 is loaded into or unloaded from the process container 203 through the substrate loading/unloading port 206 by the vacuum transfer robot 112 disposed in the vacuum transfer chamber 103 adjacent to the process chamber 201, and the placement position of the wafer 200 placed by the vacuum transfer robot 112 is controlled by the transfer robot control unit 282. That is, the placement position of the wafer 200 by the vacuum transfer robot 112 may be controlled in a desired manner according to the contents of an operation instruction from the transfer robot control unit 282. Therefore, the deformation direction of a component such as the dispersion plate 234 is regulated along the moving direction of the vacuum transfer robot 112. Although the component such as the dispersion plate 234 is deformed, a shift in relative position of the wafer 200 and the through-holes 234a of the dispersion plate 234 by the deformation may be offset through the operation of varying the movement position of the vacuum transfer robot 112.

(f) According to the first embodiment, the transfer robot control unit 282 variably controls the placement position of the wafer 200 through the vacuum transfer robot 112, depending on the processing situation of the wafer 200 within the process container 203. For example, the wafer 200 which is first loaded and processed in the process container 203 (first wafer) may be placed at the first placement position, and the wafer 200 which is loaded and processed in the process container 203 after the first wafer is processed (second wafer) may be placed at the second placement position. That is, depending on the processing situation, the placement positions of the wafers 200 may be differently set. Therefore, although a component such as the dispersion plate 234 is deformed by the influence of a process of heating the wafer 200, the deformation may be properly handled, and the relative position of the wafer 200 and the through-holes 234a of the dispersion plate 234 may be constantly retained.

(g) In the first embodiment, the common gas supply pipe which alternately supplies the first processing gas (first element-containing gas) and the second processing gas (second element-containing gas) is connected to the shower head 230. Thus, materials (byproducts) which do not contribute to film formation may be generated to change the quality of the film formed on the wafer 200, for example, the property such as the density and thickness of the film. Even in this case, according to the first embodiment, the relative position of the wafer 200 and the through-holes 234a of the dispersion plate 234 can be constantly retained from the first wafer 200 to the last wafer 200 of the first lot or from the first wafer 200 to the last wafer 200 of a corresponding lot among the plurality of lots. That is, the first embodiment may be efficiently applied to the case in which different processing gases are alternately supplied.

### Second Embodiment

Next, a second embodiment described herein will be described. The descriptions of the second embodiment will be focused on differences from the first embodiment, and the descriptions of the same components as those of the first embodiment will be omitted herein.

[Apparatus Configuration]

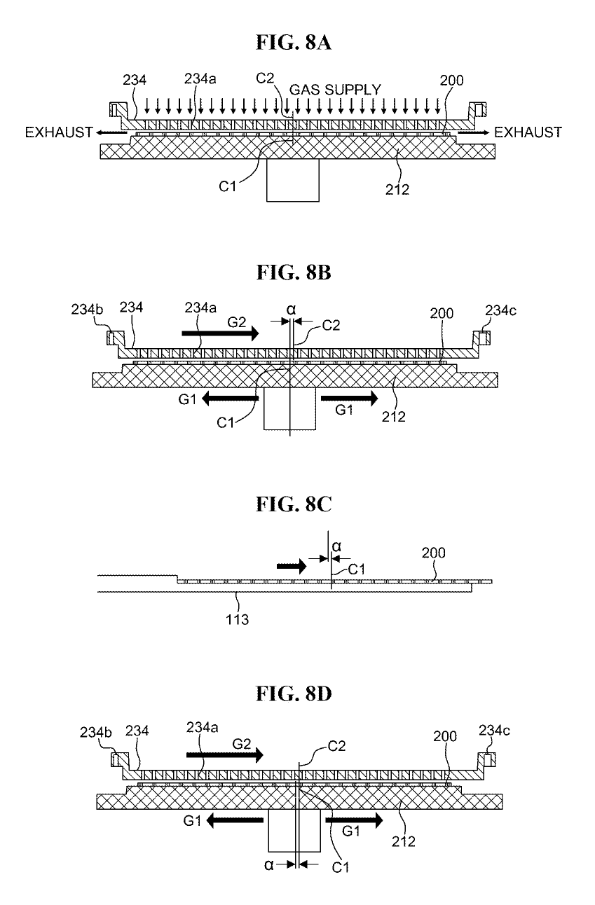

FIG. 9 is a diagram illustrating a transverse cross-section of the entire configuration of a substrate processing apparatus according to a second embodiment. The substrate processing apparatus exemplified in FIG. 9 is different from the substrate processing apparatus according to the first embodiment in that each of the process modules 201a through 201d includes a plurality of process chambers (for example, two process chambers). Specifically, the process module 201a includes two process chambers 202a and 202b, the process module 201b includes two process chambers 202c and 202d, the process module 201c includes two process chambers 202e and 202f, and the process module 201d includes two process chambers 202g and 202h.

A plurality of substrate loading/unloading ports 206a through 206h corresponding to the respective process chambers 202a through 220h are installed in the process modules 201a through 201d. The substrate loading/unloading ports 206a through 206h are installed at the walls of the process modules 201a through 201d. Thus, the substrate loading/unloading ports 206a through 206h face the same point, or specifically the vacuum transfer chamber 103. The substrate loading/unloading port 206a through 206h can be opened/closed by gate valves 161a through 161h.

The vacuum transfer robot 112 disposed in the vacuum transfer chamber 103 facing the substrate loading/unloading ports 206a through 206h includes a plurality of end effectors 113a and 113b, for example, two end effectors which correspond to the plurality of substrate loading/unloading ports 206a through 206h facing the same point, and are formed at the front ends of an arm bifurcated into two parts. Since the end effectors 113a and 113b are formed at the front ends of the arm bifurcated into two parts, the end effectors 113a and 113b are operated in synchronization with each other. In the second embodiment, “operated in synchronization” indicates that the end effectors 113a and 113b are operated at the same timing along the same direction.

[Placement Position of Substrate]

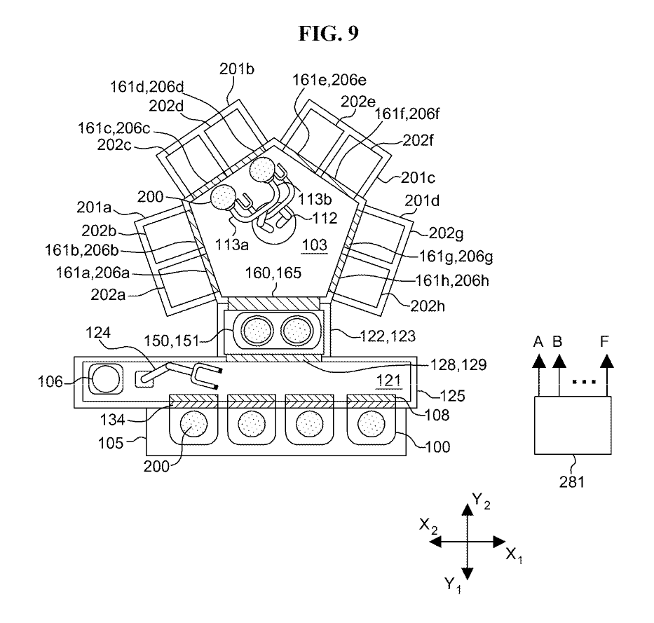

Next, in the second embodiment, a position at which the wafer 200 is placed, that is, a placement position will be described. FIG. 10 is a diagram illustrating the configuration of main portions of the process chamber of the substrate processing apparatus according to the second embodiment.

For the placement position, one of the process modules 201a through 201d will be taken as an example for description. Since one of the process modules 201a through 201d is exemplified, the process modules 201a through 201d are simply referred to as “process modules 201” in the following descriptions. Furthermore, among the process chambers 202a through 202h installed in the respective process modules 201a through 201d, the process chambers 202a, 202c, 202e and 202g which are positioned at the left side when seen from the vacuum transfer chamber 103 are simply referred to as “process chambers 202L”, the process chambers 202b, 202d, 202f and 202h which are positioned at the right side when seen from the vacuum transfer chamber 103 are simply referred to as “process chambers 202R”, and the gate valves 161a through 161h corresponding to the process chambers 202a through 202h, respectively, are simply referred to as “gate valves 161H” or “gate valves 161R”.

The process module 201 includes two process chambers 202L and 202R. The wafer 200 is loaded into or unloaded from the process chamber 202L by the end effector 113a of the vacuum transfer robot 112. The wafer 200 is loaded into or unloaded from the process chamber 202R by the end effector 113b of the vacuum transfer robot 112. The gate valves 161L and 161R corresponding to the process chambers 202l and 202R are installed at the wall of the process module 201. The end effectors 113a and 113b are operated in synchronization with each other. Thus, as the vacuum transfer robot 112 is operated at the same timing and in the same direction, the wafers 200 is loaded into or unloaded from the process chambers 202L and 202R. That is, the operation of loading or unloading the wafers 200 into the process chambers 202L and 202R is efficiently performed on a basis of the process module 201.

Furthermore, the position of the dispersion plate 234 within each of the process chambers 202L and 202R is regulated by the first and second position regulating parts 235 and 236 which are arranged according to the loading/unloading direction of the wafer 200. Therefore, although a component such as the dispersion plate 234 is deformed (extended) by the influence of the process of heating the wafer 200 in each of the process chambers 202L and 202R, the deformation direction may be regulated along the moving direction of the end effectors 113a and 113b of the vacuum transfer robot 112. That is, although the process module 201 includes two process chambers 202L and 202R, the same effect as the first embodiment can be obtained. Specifically, although the relative position of the wafer 200 and the through-holes 234a of the dispersion plate 234 is shifted by the deformation of the dispersion plate 234 due to the influence of the heating process, the shift can be offset. Furthermore, the relative position of the wafer 200 on the substrate placing surface 211 and the through-holes 234a of the dispersion plate 234 can be constantly retained.

[Cooling Mechanism]

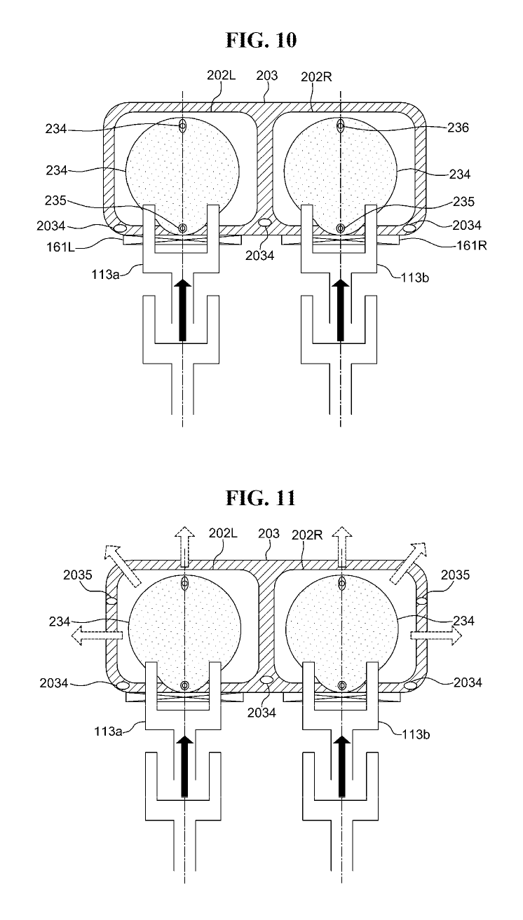

In the second embodiment, a cooling pipe 2034 constituting the cooling mechanism may be disposed at a side where the gate valves 161L and 161R of the process module 201 are disposed (refer to FIG. 10), as in the first embodiment. In the second embodiment, however, one process module 201 includes two process chambers 202L and 202R which are disposed adjacent to each other, unlike the first embodiment. Thus, the cooling pipe 2034 (2035 of FIG. 11) constituting the cooling mechanism may be disposed as described later.

FIG. 11 is a diagram illustrating a configuration of main portions of a process chamber of the substrate processing apparatus according to the second embodiment. The process of heating the wafer 200 in each of the process chambers 202L and 202R deforms (extends) components such as the substrate placing table 212 and the dispersion plate 234. At this time, the deformation may occur not only in a direction following the loading/unloading direction of the wafer 200, but also in a direction crossing the loading/unloading direction. The two process chambers 202L and 202R are disposed adjacent to each other. Therefore, the deformation in the direction crossing the loading/unloading direction of the wafer 200 in the process chamber 202L is blocked from occurring toward the process chamber 202R due to the presence of the adjacent process chamber 202R, and mainly occurs toward the opposite side as indicated by dotted arrows in FIG. 11. Furthermore, the deformation in the direction crossing the loading/unloading direction of the wafer 200 in the process chamber 202R is blocked from occurring toward the process chamber 202L due to the presence of the adjacent process chamber 202L, and mainly occurs toward the opposite side as indicated by dotted arrows in FIG. 11. As such, the concentration in occurrence direction of the deformation (extension) makes it difficult to constantly retain the relative position between the wafer 200 on the substrate placing surface 211 and the through-holes 234a of the dispersion plate 234.

Therefore, when the process chambers 202L and 202R are disposed adjacent to each other as in the second embodiment, a cooling pipe 2035 may be further installed in addition to the cooling pipe 2034 installed near the substrate loading/unloading port 206. A refrigerant is not supplied to the portion where the process chambers 202L and 202R are in contact with each other, but supplied to an outer wall portion (where the deformation is concentrated) through a temperature control unit (not illustrated) and the cooling pipe 2035.

When the cooling pipe 2035 is installed, the vicinities of the outer wall portion where the cooling pipe 2035 is installed are cooled by a refrigerant flowing through the cooling pipe 2035. Therefore, even when the process chambers 202L and 202R are disposed adjacent each other, the concentration in occurrence direction of the deformation (extension) by the influence of the heating process can be suppressed.

[Effects of Second Embodiment]

According to the second embodiment, the following effects can be obtained in addition to the effects of the first embodiment.

(h) In the second embodiment, the process module 201 includes the plurality of process chambers 202L and 202R, and the plurality of substrate loading/unloading ports 206 corresponding to the respective process chambers 202L and 202R face the same point. Thus, since the operation of loading or unloading the wafers 200 into or from the process chambers 202L and 202R can be performed on a basis of the process module 201, the efficiency of the loading or unloading process can be improved, and the throughput of the process of processing wafer 200 can be improved.

(i) In the second embodiment, the vacuum transfer robot 112 includes the plurality of end effectors 113a and 113b corresponding to the respective process chambers 202L and 220R, and the end effectors 113a and 113b are operated in synchronization with each other. Thus, although the process module 201 includes the plurality of process chambers 202L and 202R, a shift in relative position of the wafer 200 and the through-holes 234a of the dispersion plate 234 by the deformation of the dispersion plate 234 due to the influence of the heating process can be offset, and the relative position of the wafer 200 on the substrate placing surface 211 and the through-holes 234a of the dispersion plate 234 can be constantly retained.

### Other Embodiments

So far, the first and second embodiments have been described in detail. However, the technique described herein is not limited to the above-described embodiments, but may be modified in various manners without departing the scope of the present disclosure.

For example, in the above-described embodiments, the substrate processing apparatus performs the film forming process by alternately supplying DCS gas used as the first element-containing gas (first processing gas) and NH₃ gas used as the second element-containing gas (second processing gas), thereby forming the SiN film on the wafer 200. However, the technique described herein is not limited thereto. That is, the processing gas used for the film forming process is not limited to DCS gas and NH₃ gas, but different types of gases may be used to form different types of thin films. Furthermore, although three or more types of processing gases are used, the technique described herein can be applied as long as the processing gases can be repetitively supplied to perform the film forming processes. Specifically, the first element may include elements such as titanium (Ti), zirconium (Zr) and hafnium (Hf), in addition to silicon (Si). The second element may include elements such as oxygen (O), in addition to nitrogen (N).

Moreover, in the above-described embodiments, the film forming process has been exemplified as a process performed by the substrate processing apparatus. However, the technique described herein is not limited thereto. That is, the technique described herein may be applied to other film forming processes as well as the film forming process exemplified in the above-described embodiments. The technique described herein may be applied to a process of forming another film, instead of the thin film exemplified in the embodiments. Furthermore, regardless of the specific contents of the substrate treatment, the technique described herein may be applied to other substrate treatments such as annealing, diffusion, oxidation, nitridation and lithography, in addition to the film forming process. The technique described herein may applied to other substrate processing apparatuses such as an annealing apparatus, etching apparatus, oxidizing apparatus, nitriding apparatus, exposure apparatus, coating apparatus, drying apparatus, heating apparatus and processing apparatus using plasma. The technique described herein may also be applied when the apparatuses are mixed and used. Furthermore, a part of components according to a specific embodiment may be replaced with components of another embodiment, and components of another embodiment may be added to components of a specific embodiment. Furthermore, a part of components of each embodiment may be added as other components, deleted or replaced.

For example, in the above-described embodiments, the heater 213 is described as one of heating units. However, the technique described herein is not limited thereto. For example, the respective embodiments may include other heating sources as long as they can heat the substrate or process chamber. For example, a heating lamp structure or resistance heater may be installed at the bottom or side of the substrate placing table 212.

According to the technique described herein, although the shower head is used to supply gas onto a substrate, the process of heating the substrate can be prevented from having adverse effects on the supply of the gas.

What is claimed is:

1. A substrate processing apparatus comprising:
a process module having a process chamber where a substrate is processed;
a substrate loading/unloading port installed at one of walls defining the process module;
a cooling mechanism installed about the substrate loading/unloading port;
a substrate support disposed in the process chamber and having a substrate placing surface where the substrate is placed;
a heating unit configured to heat the substrate;
a shower head disposed to face the substrate placing surface, the shower head including a dispersion plate made of a material having a first thermal expansion rate;
a dispersion plate supporting unit configured to support the dispersion plate, wherein the dispersion plate supporting unit is made of a material having a second thermal expansion rate different from the first thermal expansion rate;
a first position regulating part disposed at a side where substrate loading/unloading port is installed, wherein the first position regulating part is configured to regulate positions of the dispersion plate and the dispersion plate supporting unit; and
a second position regulating part disposed at a side opposite to the side where substrate loading/unloading port is installed with the process chamber therebetween and in-line with the first position regulating part along a substrate loading/unloading direction, wherein the second position regulating part is configured to regulate the positions of the dispersion plate and the dispersion plate supporting unit.

2. The substrate processing apparatus of claim 1, wherein the first position regulating part comprises: a first convex portion; and a first circular concave portion where the first convex portion is inserted.

3. The substrate processing apparatus of claim 2, wherein the second position regulating part comprises: a second convex portion; and a second elliptical concave portion where the second convex portion is inserted, the second elliptical concave portion having a major axis along the substrate loading/unloading direction.

4. The substrate processing apparatus of claim 3, wherein the first position regulating part and the second position regulating part are disposed along a virtual line extending in the substrate loading/unloading direction and passing through a center of the substrate loading/unloading port.

5. The substrate processing apparatus of claim 2, wherein the first position regulating part and the second position regulating part are disposed along a virtual line extending in the substrate loading/unloading direction and passing through a center of the substrate loading/unloading port.

6. The substrate processing apparatus of claim 2, further comprising:
a transfer chamber disposed adjacent to the process module;
a transfer robot disposed in the transfer chamber, wherein the transfer robot is configured to load and unload the substrate through the substrate loading/unloading port; and
a transfer robot controller configured to control the transfer robot to adjust a placement position of the substrate where the substrate is placed on the substrates support.

7. The substrate processing apparatus of claim 6, wherein the transfer robot controller is further configured to control the transfer robot to vary the placement position such that a first placement position where a first substrate is placed differs from a second placement position where a second substrate processed after the first substrate is placed.

8. The substrate processing apparatus of claim 7, wherein the transfer robot controller comprises:
a detection unit configured to detect an operation parameter of the transfer robot; and
a calculation unit configured to calculate an operation data of the transfer robot based on the operation parameter detected by the detection unit and at least one piece of position information of the first placement position and the second placement parameter.

9. The substrate processing apparatus of claim 2, wherein the process module comprises a plurality of process chambers, and a plurality of substrate loading/unloading ports of the plurality of process chambers face a same point.

10. The substrate processing apparatus of claim 9, wherein the transfer robot comprises a plurality of end effectors corresponding to the plurality of substrate loading/unloading ports facing a same point, and plurality of end effectors is operated in synchronization.

11. The substrate processing apparatus of claim 1, wherein the second position regulating part comprises: a second convex portion having a pin shape; and a second elliptical concave portion where the second convex portion is inserted, the second elliptical concave portion having a major axis along the substrate loading/unloading direction.

12. The substrate processing apparatus of claim 11, wherein the first position regulating part and the second position regulating part are disposed along a virtual line extending in the substrate loading/unloading direction and passing through a center of the substrate loading/unloading port.

13. The substrate processing apparatus of claim 12, wherein the process module comprises a plurality of process chambers, and a plurality of substrate loading/unloading ports of the plurality of process chambers face a same point.

14. The substrate processing apparatus of claim 13, wherein the transfer robot comprises a plurality of end effectors corresponding to the plurality of substrate loading/unloading ports facing a same point, and plurality of end effectors is operated in synchronization.

15. The substrate processing apparatus of claim 1, wherein the first position regulating part and the second position regulating part are disposed along a virtual line extending in the substrate loading/unloading direction and passing through a center of the substrate loading/unloading port.

16. The substrate processing apparatus of claim 15, wherein the process module comprises a plurality of process chambers, and a plurality of substrate loading/unloading ports of the plurality of process chambers face a same point.

17. The substrate processing apparatus of claim 16, wherein the transfer robot comprises a plurality of end effectors corresponding to the plurality of substrate loading/unloading ports facing a same point, and plurality of end effectors is operated in synchronization.

18. The substrate processing apparatus of claim 1, wherein the process module comprises a plurality of process chambers, and a plurality of substrate loading/unloading ports of the plurality of process chambers face a same point.

19. The substrate processing apparatus of claim 18, wherein the transfer robot comprises a plurality of end effectors corresponding to the plurality of substrate loading/unloading ports facing a same point, and plurality of end effectors is operated in synchronization.
